(19) United States
(12) Patent Application Publication
(10) Pub. No.: US 2025/0280677 A1
(43) Pub. Date: Sep. 4, 2025

(54) DISPLAY APPARATUS

(71) Applicant: LG Display Co., Ltd., Seoul (KR)

(72) Inventors: Binn Kim, Paju-si (KR); Seongku Lee, Paju-si (KR)

(73) Assignee: LG Display Co., Ltd., Seoul (KR)

(21) Appl. No.: 18/962,644

(22) Filed: Nov. 27, 2024

(30) Foreign Application Priority Data
Feb. 29, 2024 (KR) 10-2024-0029825

(51) Int. Cl. H10K 59/131; H10K 59/35; H10K 59/38

(52) U.S. Cl. CPC H10K 59/131; H10K 59/351; H10K 59/38

(57) ABSTRACT

A display apparatus according to an embodiment of the present disclosure comprising: a first pixel comprising a first sub-pixel including a first circuit area and a first light emission area, and disposed in a first direction; a second pixel disposed adjacent to the first pixel in the first direction, and comprising another first sub-pixel including a second circuit area and a second light emission area and emitting light with the same color as the first sub-pixel; a first data line disposed on one side of the first circuit area in a second direction; and a first share connection line connecting the first data line to each of the first circuit area and the second circuit area.

### CROSS-REFERENCE TO RELATED APPLICATIONS

This application claims priority to Korean Patent Application No. 10-2024-0029825, filed in the Republic of Korea on Feb. 29, 2024, the entire contents of which are hereby expressly incorporated by reference as if fully set forth herein into the present application.

### BACKGROUND

### Field of the Invention

The present disclosure relates to a display apparatus (also referred to herein as a display device).

### Discussion of the Related Art

Since an organic light emitting display apparatus has a high response speed and low power consumption and self-emits light without requiring a separate light source unlike a liquid crystal display apparatus, there is no problem in a viewing angle. Thus, the organic light emitting display apparatus has received attention as a next-generation flat panel display apparatus.

Such a display apparatus displays an image through the light emission of a light emitting element layer that includes a light emitting layer interposed between two electrodes.

On the other hand, the display apparatus reduces the number of drive integrated circuits (ICs) (or data drive ICs) by having two sub-pixels for emitting light of different colors share one data line to reduce manufacturing costs. In order to connect the two sub-pixels for emitting different colors to the one data line, the circuit area of each sub-pixel can have a structure that is inverted up and down or left and right from each other. The display apparatus having such an inverted structure displays a monochromatic pattern, for example, in the case of red light emission, the voltage of each sub-pixel varies depending on the order of data input, resulting in a large number of data swings, which can cause the drive IC to heat up and reduce its lifespan.

In addition, in a display device having an inversion structure, since the circuit area of each of two sub-pixels connected to one data line has an inverted structure, a distance deviation (or parasitic cap deviation) between the scan line and the circuit area (or the gate node of the drive transistor) can occur due to the process deviation, which in turn can cause a problem that the image quality is reduced.

### SUMMARY OF THE DISCLOSURE

The present disclosure is to provide a display device that can reduce the number of drive ICs while preventing the drive ICs from heating up.

The present disclosure is to provide a display device that can reduce the number of drive ICs while avoiding image quality degradation.

The present disclosure is to provide a display device in which the lifetime of a drive IC can be improved, resulting in reduced power consumption.

The technical benefits of the present disclosure are not limited to the above-mentioned benefits, and other benefits, which are not mentioned above, can be clearly understood by those skilled in the art from the following descriptions.

A display apparatus according to an embodiment of the present disclosure can comprise a first pixel comprising a first sub-pixel including a first circuit area and a first light emission area, disposed in a first direction; a second pixel disposed adjacent to the first pixel in the first direction, and comprising another first sub-pixel including a second circuit area and a second light emission area and emitting light with the same color as the first sub-pixel; a first data line disposed on one side of the first circuit area in a second direction; and a first share connection line connecting the first data line to each of the first circuit area and the second circuit area.

A display apparatus according to another embodiment of the present disclosure comprises: a first pixel and a second pixel disposed adjacent to each other in a first direction, the first pixel comprising a first sub-pixel including a first circuit area and a first light emission area, the second pixel comprising another first sub-pixel including a second circuit area and a second light emission area, the first sub-pixel and the another first sub-pixel emitting light of the same color; a first data line extending in a second direction intersecting with the first direction, and disposed on one side of the first circuit area; a first share connection line connecting the first data line to each of the first circuit area and the second circuit area; and a first gate line extending in the first direction, and disposed adjacent to the first sub-pixel.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a display device according to one embodiment of the present disclosure.

FIG. 2 is an enlarged, schematic view of portion A shown in FIG. 1.

FIG. 3 is a schematic cross-sectional view of the line I-I′ shown in FIG. 2.

FIG. 4 is a schematic cross-sectional view of the line II-II′ shown in FIG. 2.

FIG. 5 is a schematic partial plan view illustrating a plurality of pixels including scan transistors of a display device according to one embodiment of the present disclosure.

FIG. 6 is an enlarged plan view of portion A shown in FIG. 1.

FIG. 7 is a schematic cross-sectional view of the line II-I′ shown in FIG. 6.

FIG. 8 is a schematic cross-sectional view of the line II-II″ shown in FIG. 6.

FIG. 9 is a schematic plan view of one pixel shown in FIG. 6.

FIG. 10 is a schematic plan view of a display device according to a second embodiment of the present disclosure.

FIG. 11 is a schematic cross-sectional view of a display device according to a third embodiment of the present disclosure.

FIG. 12 is a schematic plan view illustrating an example variation of a display device according to one embodiment of the present disclosure.

FIG. 13 is a schematic plan view illustrating another example variation of a display device according to one embodiment of the present disclosure.

FIG. 14 is a schematic plan view illustrating another example variation of a display device according to one embodiment of the present disclosure.

### DETAILED DESCRIPTION OF THE EMBODIMENTS

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part can be added unless ‘only’ is used. The terms of a singular form can include plural forms unless referred to the contrary.

In construing an element, the element is construed as including an error range although there is no explicit description.

In describing a position relationship, for example, when a position relation between two parts is described as ‘on’, ‘over’, ‘under’, and ‘next’, one or more other parts can be disposed between the two parts unless ‘just’ or ‘direct’ is used.

In describing a temporal relationship, for example, when the temporal order is described as “after,” “subsequent,” “next,” and “before,” a case which is not continuous can be included, unless “just” or “direct” is used. It will be understood that, although the terms “first,” “second,” etc. can be used herein to describe various elements, these elements should not be limited by these terms.

These terms are only used to distinguish one element from another. For example, a first element could be termed a second element, and, similarly, a second element could be termed a first element, without departing from the scope of the present disclosure.

Here, “X-axis direction”, “Y-axis direction” and “Z-axis direction” should not be construed by a geometric relation only of a mutual vertical relation and can have broader directionality within the range that elements of the present disclosure can act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item. Further, the term “can” fully encompasses all the meanings and coverages of the term “may.”

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship.

Hereinafter, various embodiments of the present disclosure will be described in detail with reference to the accompanying drawings. All the components of each display device or apparatus according to all embodiments of the present disclosure are operatively coupled and configured.

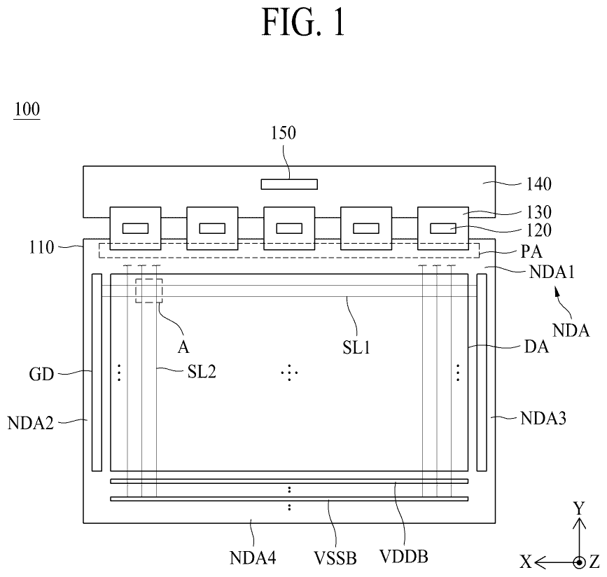

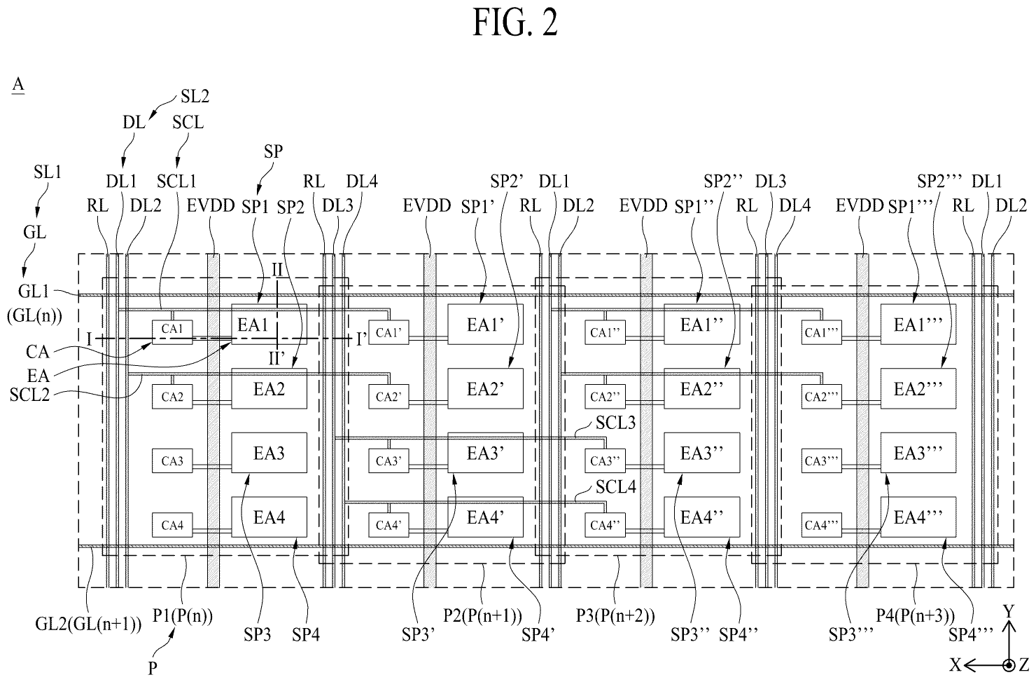

FIG. 1 is a schematic plan view of a display device according to one embodiment of the present disclosure, and FIG. 2 is an enlarged, schematic view of portion A shown in FIG. 1.

Hereinafter, the X-axis direction indicates a direction in parallel to the first line SL1 (e.g., a gate line) in a first direction, the Y-axis direction indicates a direction in parallel to the second line SL2 (e.g., a data line) in a second direction, and the Z-axis direction indicates a thickness direction of the display device 100 in a third direction intersecting with each of the X-axis direction and the Y-axis direction.

Referring to FIG. 1, the display apparatus 100 according to one embodiment of the present disclosure can include a display panel having a gate driver GD, a source drive integrated circuit (hereinafter, referred to as “IC”) 120, a flexible film 130, a circuit board 140, and a timing controller 150.

The display panel can include a substrate 110 having a display area DA in which a plurality of pixels P, each having a plurality of sub-pixels SP in FIG. 2, are disposed, and a non-display area NDA disposed on the periphery of the display area DA.

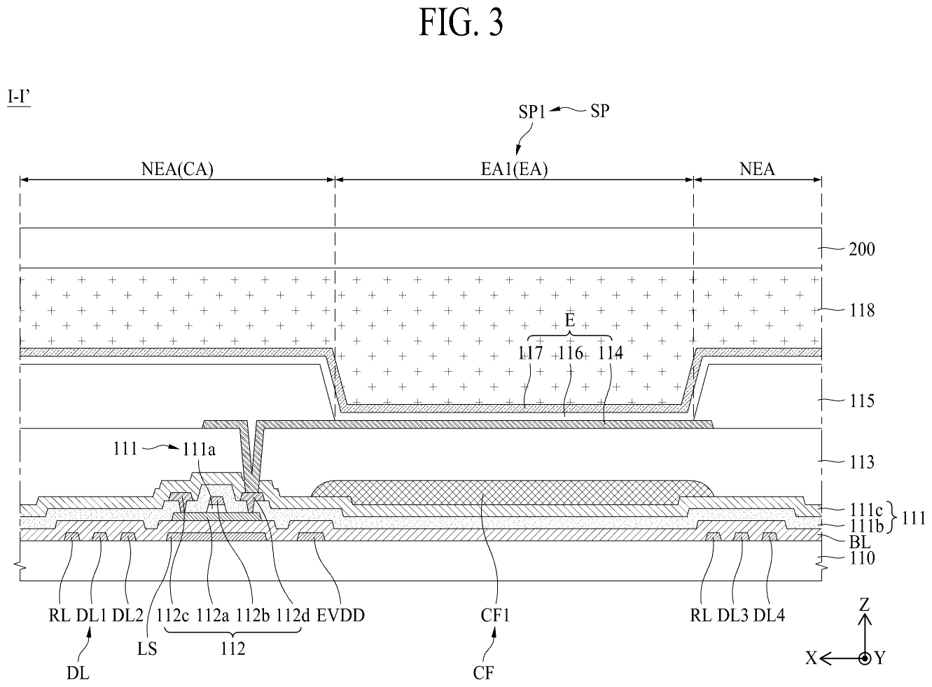

The display panel can include a substrate 110 and an opposite substrate 200 (shown in FIG. 3) bonded together.

The substrate 110 can include a thin film transistor, and can be a transistor array substrate, a lower substrate, a base substrate, or a first substrate. The substrate 110 can be a transparent glass substrate or a transparent plastic substrate.

The opposite substrate 200 can be bonded to the substrate 110 via an adhesive member. For example, the opposite substrate 200 can have a size smaller than that of the substrate 110, and can be bonded to the remaining portion except the pad area of the substrate 110. The opposite substrate 200 can be an upper substrate, a second substrate, or an encapsulation substrate.

The gate driver GD supplies gate signals to the gate lines in accordance with the gate control signal input from the timing controller 150. When the source drive IC 120 is manufactured as a driving chip, the source drive IC 120 can be packaged in the flexible film 140 in a chip on film (COF) method or a chip on plastic (COP) method.

Pads such as power pads and data pads can be formed in a non-display area of a display panel. A flexible film 130 can include lines connecting the pads to a source drive IC 120 and lines connecting the pads to lines of a circuit board 140. The flexible film 130 can be attached to the pads by using an anisotropic conducting film, whereby the pads can be connected to the lines of the flexible film 130.

The substrate 110 according to an example can include a display area DA and a non-display area NDA.

The display area DA is an area where an image is displayed, and can be a pixel array area, an active area, a pixel array unit, a display unit, or a screen. For example, the display area DA can be disposed at a central portion of the display panel. The non-display area NDA can surround the display area DA entirely or only in part(s).

The display area DA according to an example can include gate lines, data lines, pixel driving power lines, and a plurality of pixels P (shown in FIG. 2). Each of the plurality of pixels P can include a plurality of sub-pixels SP that can be defined by the gate lines and the data lines.

Each of the plurality of sub-pixels SP can be defined as a minimum unit area in which light is actually emitted.

According to one example, at least four sub-pixels, which are provided to emit light of different colors and disposed to be adjacent to one another, among the plurality of sub-pixels SP constitute one unit pixel P. One unit pixel can include, but is not limited to, a red sub-pixel, a white sub-pixel, a green sub-pixel, a blue sub-pixel. According to another example, three sub-pixels SP, which are provided to emit light of different colors and disposed to be adjacent to one another, among the plurality of sub-pixels SP constitute one unit pixel. One unit pixel can include at least one red sub-pixel, at least one green sub-pixel, at least one blue sub-pixel, but is not limited thereto.

Each of the plurality of sub-pixels SP can include a thin film transistor and a light emitting element connected to the thin film transistor. The sub-pixel can include a light emitting layer (or an organic light emitting layer) interposed between a first electrode and a second electrode.

The light emitting layer disposed in each of the plurality of sub-pixels SP can individually emit light of different colors, or can commonly emit white light. According to one example, when the light emitting layer of each of the plurality of sub-pixels SP commonly emits white light, each of the red sub-pixel, the green sub-pixel and the blue sub-pixel can include a color filter (or a wavelength conversion member) for converting the white light into light of different colors. In this case, the white sub-pixel according to one example may not include a color filter. The color filter CF, according to one example, can include a red color filter CF1, a blue color filter CF2, and a green color filter CF3.

In the transparent display apparatus 100 according to one embodiment of the present disclosure, an area in which a red color filter CF1 is provided can be a red sub-pixel SP1, an area in which a blue color filter CF2 is provided can be a blue sub-pixel SP3, an area in which a green color filter CF3 is provided can be a green sub-pixel SP4, and an area in which a color filter is not provided can be a white sub-pixel SP2. In the present disclosure, the red sub-pixel SP1 can be expressed as a first sub-pixel provided to emit red light, the blue sub-pixel SP3 can be expressed as a third sub-pixel configured to emit blue light, the green sub-pixel SP4 can be expressed as a fourth sub-pixel provided to emit green light, and the white sub-pixel SP2 can be represented as a second sub-pixel provided to emit white light.

Each of the plurality of sub-pixels SP supplies a predetermined current to the organic light emitting element in accordance with a data voltage of the data line when a gate signal is input from the gate line by using the thin film transistor. For this reason, the light emitting layer of each of the sub-pixels can emit light with a predetermined brightness in accordance with the predetermined current.

As shown in FIG. 3, the display area DA includes a light emission area EA and a non-light emission area NEA. The light emission area EA is an area in which an organic light emission layer emits light due to the formation of an electric field of the anode electrode and the cathode electrode, and the non-light emission area NEA is an area that does not transmit most of the light incident from the outside. For example, the non-light emission area NEA can be an area excluding the light emission area EA in which light is emitted. In one example, the non-light emission area NEA can be provided between the plurality of sub-pixels SP on the substrate 110. As shown in FIG. 2, the display area DA can further comprise a circuit area CA for driving each of the plurality of sub-pixels SPs.

In the non-light emission area NEA, the plurality of pixels P and a plurality of wirings for driving each of the plurality of pixels P can be disposed. The plurality of wirings, according to one example, can include a plurality of first signal lines SL1 and a plurality of second signal lines SL2.

The plurality of first signal lines SL1 can be long extended in the first direction (X-axis direction). Each of the plurality of first signal lines SL1 can include at least one scan line.

Hereinafter, when the first signal line SL1 includes a plurality of lines, one first signal line SL1 can refer to a signal line group comprised of a plurality of lines. For example, when the first signal line SL1 includes two scan lines, one first signal line SL1 can refer to a signal line group comprised of two scan lines.

The plurality of second signal lines SL2 can extend in the second direction (Y-axis direction). The plurality of second signal lines SL2 can intersect with the plurality of first signal lines SL1. Each of the plurality of second signal lines SL2 can include a pixel power line EVDD, a common power line, a plurality of data lines DL, and a reference line RL.

Hereinafter, when the second signal line SL2 includes a plurality of lines, one second signal line SL2 can refer to a signal line group comprised of a plurality of lines. For example, when the second signal line SL2 includes four data lines, a pixel power line, a common power line and a reference line, one second signal line SL2 can refer to a signal line group comprised of four data lines, a pixel power line, a common power line and a reference line.

Referring back to FIG. 1, the non-display area NDA is an area on which an image is not displayed, and can be a peripheral circuit area, a signal supply area, an inactive area or a bezel area. The non-display area NDA can be configured to be in the vicinity of the display area DA. For example, the non-display area NDA can be disposed to surround the display area DA.

The transparent display apparatus 100 according to one embodiment of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images. The non-display area NDA can include a first non-display area NDA1, a second non-display area NDA2, a third non-display area NDA3, and a fourth non-display area NDA4. The pad portion PA according to one example can be disposed in the first non-display area NDA1.

The gate driver GD supplies gate signals to the gate lines in accordance with the gate control signal input from the timing controller 150. The gate driver GD can be formed on one side of the display area DA of the display panel or on the non-display area NDA outside both sides of the display area DA in a gate driver in panel (GIP) method as shown in FIG. 1. Alternatively, the gate driver GD can be manufactured as a driving chip, packaged in a flexible film and attached to the non-display area NDA outside one side or both sides of the display area DA of the display panel by a tape automated bonding (TAB) method.

The plurality of gate drivers GD can be separately disposed on a left side of the display area DA, for example, the second non-display area NDA2 and a right side of the display area DA, for example, the third non-display area NDA3. According to one example, the plurality of gate drivers GD can be connected to the plurality of pixels P and the plurality of first signal lines SL1 for supplying signals to the plurality of pixels P. The plurality of first signal lines SL1 can include at least one signal line for supplying a signal for driving the pixel P.

The plurality of second signal lines SL2 can be extended in the second direction (Y-axis direction). The plurality of second signal lines SL2 can cross the plurality of first signal lines SL1. The plurality of second signal lines can include a pixel power line VDD and at least one data line to supply a data voltage to the pixel P. Each of the plurality of second signal lines SL2 can be connected to at least one of a plurality of pads, a pixel power shorting bar VDDB or a common power shorting bar VSSB. The pixel power shorting bar VDDB and the common power shorting bar VSSB can be disposed in the fourth non-display area NDA4 that is disposed to face the pad area PA based on the display area DA.

The pixels are provided to overlap at least one of the first signal line SL1 or the second signal line SL2 and emit predetermined light to display an image. The light emission area EA can correspond to an area, which emits light, in the pixel P.

The non-light emission area NEA can refer to an area that is provided in the display area DA and does not emit light, and can be expressed as a dead zone because it does not emit light. The dead zone according to one example can be an area in which a black matrix and/or a bank is provided, but is not limited thereto, and can refer to an area in which light is not emitted.

The non-light emission area NEA can have the plurality of wirings, for example, first signal lines SL1 and second signal lines SL2 can be disposed.

The first signal lines SL1 according to one example can include a plurality of gate lines GL extending in the first direction (X-axis direction). The plurality of gate lines GL according to one example can include a first gate line GL1, a second gate line GL2, a third gate line GL3, and a fourth gate line GL4. The first signal line SL1 can include the plurality of gate lines GL, thus the first gate line GL1 can be denoted as a nth gate line GLn, the second gate line GL2 can be denoted as an n+1st gate line GLn+1, and so on, the third gate line GL3 can be denoted as the n+2nd gate line GLn+2, and the fourth gate line GL4 can be denoted as the n+3rd gate line GLn+3.

The second signal lines SL2 according to one example can include the pixel power line EVDD, the common power line, the reference line RL, and a plurality of data lines DL, extending in the second direction (Y-axis direction). The plurality of data lines DL can include a first data line DL1 for driving a first sub-pixel SP1, a second data line DL2 for driving a second sub-pixel SP2, a third data line DL3 for driving a third sub-pixel SP3, and a fourth data line DL4 for driving a fourth sub-pixel SP4.

Referring to FIG. 2, the display device 100 according to one embodiment of the present disclosure can include a first pixel P1, a second pixel P2, a third pixel P3, and a fourth pixel P4. Since the display area DA includes a plurality of pixels P, the first pixel P1 can be denoted as a nth pixel Pn, the second pixel P2 can be denoted as an n+1st pixel Pn+1, the third pixel P3 can be denoted as an n+2nd pixel Pn+2, and the fourth pixel P4 can be denoted as an n+3rd pixel Pn+3.

The first pixel P1 according to one example can include a first sub-pixel SP1, a second sub-pixel SP2, a third sub-pixel SP3, and a fourth sub-pixel SP4. The second sub-pixel SP2 can be disposed adjacent to the first sub-pixel SP1 in the second direction (Y-axis direction). The third sub-pixel SP3 can be disposed adjacent to the second sub-pixel SP2 in the second direction (Y-axis direction). The fourth sub-pixel SP4 can be disposed adjacent to the third sub-pixel SP3 in the second direction (Y-axis direction).

The second pixel P2 according to one example can include another first sub-pixel SP1′, another second sub-pixel SP2′, another third sub-pixel SP3′, and another fourth sub-pixel SP4′. The another second sub-pixel SP2′ of the second pixel P2 can be disposed adjacent to the another first sub-pixel SP1′in the second direction (Y-axis direction). The another third sub-pixel SP3′ can be disposed adjacent to the another second sub-pixel SP2′ in the second direction (Y-axis direction). The another fourth sub-pixel SP4′ can be disposed adjacent to the another third sub-pixel SP3′ in the second direction (Y-axis direction). The another first sub-pixel SP1′, the another second sub-pixel SP2′, the another third sub-pixel SP3′, and the another fourth sub-pixel SP4′ included in the second pixel P2 can be a first sub-pixel SP1′, a second sub-pixel SP2′, a third sub-pixel SP3′, and a fourth sub-pixel SP4′ of the second pixel P2.

The third pixel P3 according to one example can include another first sub-pixel SP1″, another second sub-pixel SP2″, another third sub-pixel SP3″, and another fourth sub-pixel SP4″. The another second sub-pixel SP2″ of the third pixel P3 can be disposed adjacent to the another first sub-pixel SP1″ in the second direction (Y-axis direction). The another third sub-pixel SP3″ can be disposed adjacent to the another second sub-pixel SP2″ in the second direction (Y-axis direction). The another fourth sub-pixel SP4″ can be disposed adjacent to the another third sub-pixel SP3″ in the second direction (Y-axis direction). The another first sub-pixel SP1″, the another second sub-pixel SP2″, the another third sub-pixel SP3″, and the another fourth sub-pixel SP4″ included in the third pixel P3 can be a first sub-pixel SP1″, a second sub-pixel SP2″, a third sub-pixel SP3″, and a fourth sub-pixel SP4″ of the third pixel P3.

The fourth pixel P4 according to one example can include another first sub-pixel SP1″, another second sub-pixel SP2″, another third sub-pixel SP3″, and another fourth sub-pixel SP4″. Another second sub-pixel SP2″ of the fourth pixel P4 can be disposed adjacent to the another first sub-pixel SP1″ in the second direction (Y-axis direction). The another third sub-pixel SP3″ can be disposed adjacent to the another second sub-pixel SP2′″ in the second direction (Y-axis direction). The another fourth sub-pixel SP4″ can be disposed adjacent to the another third sub-pixel SP3″′ in the second direction (Y-axis direction). The another first sub-pixel SP1″, the another second sub-pixel SP2″, the another third sub-pixel SP3″, and the another fourth sub-pixel SP″ included in the fourth pixel P4 can be a first sub-pixel SP1″, a second sub-pixel SP2″, a third sub-pixel SP3″, and a fourth sub-pixel SP4″ of the third pixel P3.

The first sub-pixel SP1 of the first pixel P1, the another first sub-pixel SP1′ of the second pixel P2, and the another first sub-pixel SP1″ of the third pixel P3 can be configured to emit light with all the same color, for example, red color. The another first sub-pixel SP1″ of the fourth pixel P4 can also be configured to emit light with red color.

The second sub-pixel SP2 of the first pixel P1, the another second sub-pixel SP2′ of the second pixel P2, and the another second sub-pixel SP2″ of the third pixel P3 can be configured to emit light with all the same color, for example, white color. The another second sub-pixel SP2′′ of the fourth pixel P4 can also be configured to emit light with white color.

The third sub-pixel SP3 of the first pixel P1, the another third sub-pixel SP3′ of the second pixel P2, and the another third sub-pixel SP3″ of the third pixel P3 can be configured to emit light with all the same color, for example, blue color. The another third sub-pixel SP3″ of the fourth pixel P4 can also be configured to emit light of blue color.

The fourth sub-pixel SP4 of the first pixel P1, the another fourth sub-pixel SP4′ of the second pixel P2, and the another fourth sub-pixel SP4″ of the third pixel P3 can be configured to emit light with all the same color, for example, green color. The another fourth sub-pixel SP4″ of the fourth pixel P4 can also be configured to emit light of green color.

Accordingly, as shown in FIG. 2, the display device 100 according to one embodiment of the present disclosure can be provided with a structure in which sub-pixels SPs emitting light of the same color are disposed in a row in the first direction (X-axis direction). Each of the plurality of sub-pixels SPs according to an example can include a circuit area and a light emission area, disposed in the first direction (e.g., X-axis direction).

For example, the first sub-pixel SP1 of the first pixel P1 can include a first circuit area CA1 and a first light emission area EA1 disposed in the first direction (X-axis direction).

The another first sub-pixel SP1′ of the second pixel P2 disposed adjacent to the first pixel P1 in the first direction (X-axis direction) can emit light with the same color as the first sub-pixel SP1 of the first pixel P1, and can include a second circuit area CA′ and a second light emission area EA1′ disposed in the first direction (X-axis direction).

The another first sub-pixel SP1″ of the third pixel P3 can include a circuit area CA1″ and a light emission area EA1″ disposed in the first direction (X-axis direction), the another first sub-pixel SP1″′ of the fourth pixel P4 can include a circuit area CA1″ and a light emission area EA1″ disposed in the first direction (X-axis direction).

The second sub-pixel SP2 of the first pixel P1 can be disposed adjacent to the first sub-pixel SP1 in the second direction (e.g., Y-axis direction), can include a circuit area CA2 and a light emission area EA2 disposed in the first direction (X-axis direction). The third sub-pixel SP3 of the first pixel P1 can be disposed adjacent to the second sub-pixel SP2 in the second direction (Y-axis direction), can include a circuit area CA3 and a light emission area EA3 disposed in the first direction (X-axis direction). The fourth sub-pixel SP4 of the first pixel P1 can be disposed adjacent to the third sub-pixel SP3 in the second direction (Y-axis direction), can include a circuit area CA4 and a light emission area EA4 disposed in the first direction (X-axis direction).

The another second sub-pixel SP2′ of the second pixel P2 can be disposed adjacent to the another first sub-pixel SP1′ in the second direction (Y-axis direction), and can include a circuit area CA2′ and a light emission area EA2′ disposed in the first direction (X-axis direction). The another third sub-pixel SP3′ of the second pixel P2 can be disposed adjacent to the another second sub-pixel SP2′ in the second direction (Y-axis direction), and can include a circuit area CA3′ and a light emission area EA3′ disposed in the first direction (X-axis direction). The another fourth sub-pixel SP4′ of the second pixel P2 can be disposed adjacent to the another third sub-pixel SP3′ in the second direction (Y-axis direction), and can include a circuit area CA4′ and a light emission area EA4′ disposed in the first direction (X-axis direction).

The another second sub-pixel SP2″ of the third pixel P3 can be disposed adjacent to the another first sub-pixel SP1″ in the second direction (Y-axis direction), and can include a circuit area CA2″ and a light emission area EA2″ disposed in the first direction (X-axis direction). The another third sub-pixel SP3″ of the third pixel P3 can be disposed adjacent to the another second sub-pixel SP2″ in the second direction (Y-axis direction), and can include a circuit area CA3″ and a light emission area EA3″ disposed in the first direction (X-axis direction). The another fourth sub-pixel SP4″ of the third pixel P3 can be disposed adjacent to the another third sub-pixel SP3″ in the second direction (Y-axis direction), and can include a circuit area CA4″ and a light emission area EA4″ disposed in the first direction (X-axis direction).

The another second sub-pixel SP2″ of the fourth pixel P4 can be disposed adjacent to the another first sub-pixel SP1″ in the second direction (Y-axis direction), and can include a circuit area CA2′′ and a light emission area EA2″ disposed in the first direction (X-axis direction). The another third sub-pixel SP3″ of the fourth pixel P4 can be disposed adjacent to the another second sub-pixel SP2′ in the second direction (Y-axis direction), and can include a circuit area CA3′ and a light emission area EA3″′ disposed in the first direction (X-axis direction). The another fourth sub-pixel SP4″ of the fourth pixel P4 can be disposed adjacent to the another third sub-pixel SP3″ in the second direction (Y-axis direction), and can include a circuit area CA4′ and a light emission area EA4″′ disposed in the first direction (X-axis direction).

Thus, the second pixel P2 disposed adjacent to the first pixel P1 in the first direction (X-axis direction) can include the another first sub-pixel SP1′ emitting light with the same color as the first sub-pixel SP1, and the another first sub-pixel SP1′ of the second pixel P2 can include a second circuit area CA1′ and a second light emission area EA1′.

As a result, the display device 100 according to one embodiment of the present disclosure can be configured such that the circuit areas and light emission areas of each of the red sub-pixel SP1, the white sub-pixel SP2, the blue sub-pixel SP3, and the green sub-pixel SP4, included in each of the plurality of pixels P, are disposed in a vertical direction (or the second direction (Y-axis direction)), and sub-pixels adjacent in the first direction (X-axis direction) can be configured to emit light of the same color.

Referring again to FIG. 2, the first data line DL1 can be disposed on one side of the first circuit area CA1 in the second direction (Y-axis direction). Here, the one side of the first circuit area CA1 can mean a left side of the first circuit area CA1 with reference to FIG. 2. The first data line DL1 disposed in the second direction can means that the first data line DL1 extending in the second direction. Thus, the first data line DL1 can be spaced apart from the reference line RL in parallel. As shown in FIG. 2, the first data line DL1 according to an example can extend in the second direction (Y-axis direction) to be disposed adjacent to the circuit areas CA2, CA3, CA4 of each of the second sub-pixel SP2, the third sub-pixel SP3, and the fourth sub-pixel SP4, and the first circuit area CA1.

The display device 100 according to one embodiment of the present disclosure can include a share connection line SCL. The share connection line SCL is to connect one data line to a circuit area of one sub-pixel SP, and to a circuit area of another sub-pixel SP, respectively. Thus, the display device 100 according to one embodiment of the present disclosure can be configured such that two adjacent sub-pixels emitting light of the same color share one data line via the share connection line SCL. Therefore, the display device 100 according to one embodiment of the present disclosure can reduce the number of data lines compared to a case in which each of the sub-pixels is equipped with a data line, thereby reducing the number of drive ICs connected to the data lines thus reducing manufacturing costs.

In a general display device, two sub-pixels emitting different colors share one data line to reduce the number of drive ICs (or data drive ICs). Such a general display device has a structure in which the circuit area of each sub-pixel is inverted up and down or left and right from each other in order to connect two sub-pixels emitting different colors to one data line. A general display device having an inverted structure can display a monochromatic pattern, for example, in the case of red light emission, the voltage of each sub-pixel varies depending on the order of data input, resulting in a large number of data swings, which causes the drive IC to heat up and reduce its lifespan.

For example, when the driving transistor of the red sub-pixel and the driving transistor of the white sub-pixel are connected to the first data line, the driving transistor of the red sub-pixel and the driving transistor of the white sub-pixel connected to the nth gate line are sequentially driven according to the data input signal, and then the driving transistor of the red sub-pixel and the driving transistor of the white sub-pixel connected to the n+1st gate line can be driven. In this case, the driving transistor of the red sub-pixel and the driving transistor of the white sub-pixel have different driving voltages, thus a large number of data swings occur between the red sub-pixel and the white sub-pixel, which causes the drive IC to heat up and the lifetime is reduced.

However, the display device 100 according to one embodiment of the present disclosure is configured such that two adjacent sub-pixels SPs emitting light of the same color share one data line via the share connection line SCL, thus each of the two sub-pixels (or two sub-pixels emitting light of the same color) connected to the one data line can be applied the same driving voltage, therefore no data swing occurs, and the number of drive ICs can be reduced and the heating of the drive ICs can be prevented.

Furthermore, the display device 100 according to one embodiment of the present disclosure can have an improved lifespan of the drive IC due to the absence of data swings, which can have the effect of increasing the overall service life and consequently operating at lower power, thereby reducing the overall power consumption.

Referring again to FIG. 2, the display device 100 according to one embodiment of the present disclosure can include a plurality of share connection lines SCLs. The plurality of share connection lines SCLs can include a first share connection line SCL1, a second share connection line SCL2, a third share connection line SCL3, and a fourth share connection line SCL4.

The first share connection line SCL1 according to an example can connect the first data line DL1 to the first circuit area CA1 of the first sub-pixel SP1 included in the first pixel P1 and the second circuit area CA1′ of the another first sub-pixel SP1′ included in the second pixel P2, respectively. Thus, as shown in FIG. 2, the first share connection line SCL1 can partially overlap on the first light emission area EA1. However, it is not limited thereto, when the circuit area of one sub-pixel SP and the circuit area of another sub-pixel SP are connectable, the first share connection line SCL1 can partially overlap the light emission area of another sub-pixel SP (e.g., the second emission area of another first sub-pixel of another pixel to the left of the first pixel P1). Thus, in the display device 100 according to one embodiment of the present disclosure, the first share connection line SCL1 can partially overlap the light emission area EA1 of the first sub-pixel SP1 or the light emission area of another first sub-pixel.

As a result, the display device 100 according to one embodiment of the present disclosure can have a structural feature in which the share connection line SCL partially overlaps the light emission area of any one of the two adjacent sub-pixels SPs in order to connect one data line to a circuit area of each of the two adjacent sub-pixels SPs emitting light of the same color. However, it is not necessarily limited thereto, and depending on the circuit design, the share connection line SCL may not partially overlap the light emission area.

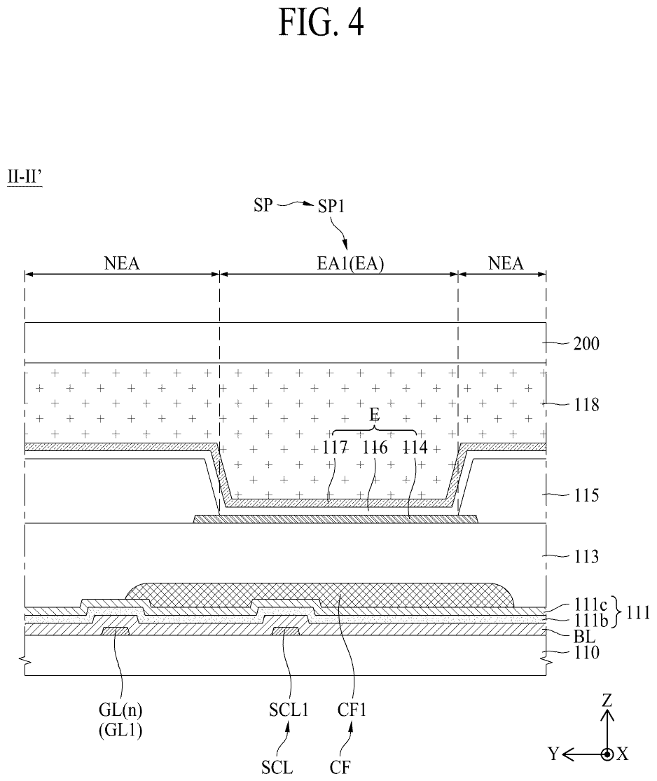

Hereinafter, with reference to FIGS. 3 and 4, the structure of each of the plurality of sub-pixels SPs will be described in detail.

FIG. 3 is a schematic cross-sectional view of the line I-I′ shown in FIG. 2, and FIG. 4 is a schematic cross-sectional view of the line II-II′ shown in FIG. 2.

Referring to FIGS. 3 and 4, a transparent display apparatus 100 according to one embodiment of the present disclosure can include a buffer layer BL, a circuit element layer 111, a thin film transistor 112, an overcoat layer 113, an anode electrode 114, a bank 115, an organic light emitting layer 116, a cathode electrode 117, a filling layer 118, and a color filter CF.

In more detail, each of the subpixels SP according to one embodiment can include a circuit element layer 111 provided on an upper surface of a buffer layer BL, including a gate insulating layer 111a, an interlayer insulating layer 111b and a passivation layer 111c, an overcoat layer 113 provided on the circuit element layer 111, a anode electrode 114 provided on the overcoat layer 113, a bank 115 covering an edge of the anode electrode 114, an organic light emitting layer 116 on the anode electrode 114 and the bank 115, a cathode electrode 117 on the organic light emitting layer 116, a filling layer 118 on the cathode electrode 117.

The thin film transistor 112 (or a drive transistor 112) for driving the subpixel SP can be disposed on the circuit element layer 111. The circuit element layer 111 can be expressed as the term of an inorganic film layer. The buffer layer BL can be included in the circuit element layer 111 together with the gate insulating layer 111a, the interlayer insulating layer 111b and the passivation layer 111c. The anode electrode 114, the organic light emitting layer 116 and the cathode electrode 117 can be included in the light emitting element layer E.

The buffer layer BL can be formed between the substrate 110 and the gate insulating layer 111a to protect the thin film transistor 112. The buffer layer BL can be disposed on the entire surface (or front surface) of the substrate 110. The pixel power line EVDD for pixel driving can be disposed between the buffer layer BL and the substrate 110. The pixel power line EVDD can be disposed below the bank 115 while being spaced apart from the thin film transistor 112. The reference line RL and the plurality of data lines DL can also be disposed between the buffer layer BL and the substrate 110. The reference line RL and the plurality of data lines DL can be disposed in the non-light emission area NEA that does not overlap with the light emission area EA. The buffer layer BL can serve to block diffusion of a material contained in the substrate 110 into a transistor layer during a high temperature process of a manufacturing process of the thin film transistor. Optionally, the buffer layer BL can be omitted in some cases.

The thin film transistor 112 (or a drive transistor) according to an example can include an active layer 112a, a gate electrode 112b, a source electrode 112c, and a drain electrode 112d.

The active layer 112a can include a channel area, a drain area and a source area, which are formed in a thin film transistor area of a circuit area of the subpixel SP. The drain area and the source area can be spaced apart from each other with the channel area interposed therebetween.

The active layer 112a can be formed of a semiconductor material based on any one of amorphous silicon, polycrystalline silicon, oxide and organic material.

The gate insulating layer 111a can be formed on the channel area of the active layer 112a. As an example, the gate insulating layer 111a can be formed in an island shape only on the channel area of the active layer 112a, or can be formed on an entire front surface of the substrate 110 or the buffer layer BL, which includes the active layer 112a.

The gate electrode 112b can be formed on the gate insulating layer 111a to overlap the channel area of the active layer 112a.

The interlayer insulating layer 111b can be formed on the gate electrode 112b and the drain area and the source area of the active layer 112a. As in FIG. 4, the interlayer insulating layer 111b can be formed in an entire light emission area, in which light is emitted to the subpixel SP. However, embodiments of the present disclosure are not limited thereto, the interlayer insulating layer 111b can be patterned between the drain electrode 112d and the gate electrode 112b and drain region of the active layer 112a and can be arranged in an island shape, and moreover, can be patterned between the source electrode 112c and the gate electrode 112b and source region of the active layer 112a and can be arranged in an island shape.

The source electrode 112c can be electrically connected to the source area of the active layer 112a through a source contact hole provided in the interlayer insulating layer 111b overlapped with the source area of the active layer 112a. The drain electrode 112d can be electrically connected to the drain area of the active layer 112a through a drain contact hole provided in the interlayer insulating layer 111b overlapped with the drain area of the active layer 112a.

The drain electrode 112d and the source electrode 112c can be made of the same metal material. For example, each of the drain electrode 112d and the source electrode 112c can be made of a single metal layer, a single layer of an alloy or a multi-layer of two or more layers, which is the same as or different from that of the gate electrode.

In addition, the circuit area can further include first and second switching thin film transistors disposed together with the thin film transistor 112, and a capacitor. Since each of the first and second switching thin film transistors is provided on the circuit area of the subpixel SP to have the same structure as that of the thin film transistor 112, its description will be omitted. The capacitor can be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the substrate 110 can further include a light shielding layer LS provided below the active layer 112a of at least one of the thin film transistor 112, the first switching thin film transistor or the second switching thin film transistor. The light shielding layer can be disposed between the substrate 110 and the active layer 112a to shield light incident on the active layer 112a through the substrate 110, thereby minimizing a change in the threshold voltage of the transistor due to external light. Further, since the light shielding layer is provided between the substrate 110 and the active layer 112a, the thin film transistor can be prevented from being seen by a user.

The passivation layer 111c can be provided on the substrate 110 to cover the pixel area. The passivation layer 111c covers a drain electrode 112d, a source electrode 112c and a gate electrode 112b of the thin film transistor 112, and the buffer layer BL.

On the other hand, as shown in FIG. 4, the pixel power line EVDD can be disposed to overlap the bank 115 in the third direction (Z-axis direction), and the reference line RL and/or the plurality of data lines DL may not overlap the bank 115 in the third direction (Z-axis direction). The passivation layer 111c can be formed over the circuit area and the light emission area. The passivation layer 111c can be omitted.

The overcoat layer 113 can be provided on the substrate 110 to cover the passivation layer 111c. When the passivation layer 111c is omitted, the overcoat layer 113 can be provided on the substrate 110 to cover the circuit area (or the thin film transistor 112). The overcoat layer 113 can be formed in the circuit area CA in which the thin film transistor 112 is disposed and the light emission area EA. In addition, the overcoat layer 113 can be formed in the other non-display area NDA except a pad area PA of the non-display area NDA and the entire display area DA. For example, the overcoat layer 113 can include an extension portion (or an enlarged portion) extended or enlarged from the display area DA to the other non-display area NDA except the pad area PA. Therefore, the overcoat layer 113 can have a size relatively wider than that of the display area DA.

The overcoat layer 113 according to one example can be formed to have a relatively thick thickness, thereby providing a flat surface on the display area DA and the non-display area NDA. For example, the overcoat layer 113 can be made of an organic material such as photo acryl, benzocyclobutene, polyimide and fluorine resin.

The color filter CF can be disposed between the overcoat layer 113 and the passivation layer 111c. As described above, the second sub-pixel SP2, which is a white sub-pixel, cannot be provided with a color filter since the organic light emission layer 116 emits white light. On the other hand, in the first sub-pixel SP1, which is a red sub-pixel, a first color filter CF1 (or red color filter CF1) can be provided between the overcoat layer 113 and the passivation layer 111c. In the third sub-pixel SP3, which is a blue sub-pixel, a second color filter CF2 (or a blue color filter) can be provided between the overcoat layer 113 and the passivation layer 111c. In the fourth sub-pixel SP4, which is a green sub-pixel, a third color filter CF3 (or a green color filter) can be provided between the overcoat layer 113 and the passivation layer 111c.

The color filter CF according to one example can convert white light of each of the plurality of sub-pixels SP into different colored light. Accordingly, the color filter CF can have a width (or size) equal to or greater than the light emission area EA. Thus, as shown in FIG. 3, the color filter CF can be disposed to overlap a portion of the bank 115.

The anode electrodes 114 according to one example can be formed on the overcoat layer 113. Since a plurality of wirings are disposed between the overcoat layer 113 and the substrate 110, the anode electrodes 114 can be disposed on the plurality of wirings. The anode electrode 114 can be connected to a drain electrode or a source electrode of the thin film transistor 112 through a contact hole passing through the overcoat layer 113 and the passivation layer 111c. The one edge portion of the anode electrode 114 can be covered by the bank 115. The anode electrode 114 can be made of at least one of a transparent metal material or a semi-transmissive metal material.

Since the display device 100 according to one embodiment of the present disclosure is bottom-emission type, the anode electrodes 114 can be formed of a transparent conductive material TCO series such as ITO, IZO, or a semi-transmissive conductive material, TMCM series such as magnesium Mg, silver Ag, or an alloy of magnesium Mg and silver Ag that is capable of transmitting light. The anode electrode 114 can be a first electrode or a pixel electrode.

As another example, when the display device 100 according to one embodiment of the present disclosure is top-emission type, the anode electrode 114 can be made of a highly reflective metallic material or a stacked structure of a highly reflective metallic material and a transparent metallic material. For example, the anode electrode 114 can be formed of a metal material having high reflectance, such as a stacked structure (Ti/Al/Ti) of aluminum and titanium, a stacked structure (ITO/Al/ITO) of aluminum and ITO, an Ag alloy, and a stacked structure (ITO/Ag alloy/ITO) of Ag alloy and ITO. The Ag alloy can be an alloy such as silver (Ag), palladium (Pd), and copper (Cu)

The bank 115 can be an area, which does not emit light, and disposed on one side of the light emission area EA of each of the plurality of sub-pixels SP. For example, the bank 115 can be disposed in the non-light emission area NEA. The bank 115 can be formed to cover a portion where the edge of the anode electrode 114. Accordingly, the bank 115 can prevent the anode electrode 114 and the cathode electrode 117 in the edge of the anode electrode 114. The exposed portion of the anode electrode 114 that is not covered by the bank 115 can be included in the light emitting portion (or light emission area EA).

After the bank 115 is formed to cover the edge of the anode electrode 114, the organic light emission layer 116 can be formed to cover the anode electrode 114 and the bank 115. Thus, in the non-light emission area NEA, the bank 115 can be provided between the anode electrode 114 and the organic light emission layer 116. The bank 115 can be expressed in terms of a pixel-defining membrane. The bank 115 according to one example can comprise organic material and/or inorganic material.

The organic light emitting layer 116 can be formed on the anode electrodes 114 and the bank 115. According to one example, the organic light emitting layer 116 can be disposed in the light emission area EA and the non-light emission area NEA. The organic light emitting layer 116 can be provided between the anode electrode 114 and the cathode electrode 117. Thus, when a voltage is applied to each of the anode electrode 114 and the cathode electrode 117, an electric field is formed between the anode electrode 114 and the cathode electrode 117. Therefore, the organic light emitting layer 116 can emit light. The organic light emitting layer 116 can be formed of a plurality of subpixels SP and a common layer provided on the bank 115.

On the other hand, the organic light emitting layer 116 according to an embodiment can be provided to emit white light. The organic light emitting layer 116 can include a plurality of stacks which emit lights of different colors. For example, the organic light emitting layer 116 can include a first stack, a second stack, and a charge generating layer (CGL) provided between the first stack and the second stack. The light emitting layer can be provided to emit the white light, and thus, each of the plurality of subpixels SP can include a color filter CF suitable for a corresponding color.

The first stack can be provided on the anode electrode 114 and can be implemented a structure where a hole injection layer (HIL), a hole transport layer (HTL), an emission layer (EML(B)), and an electron transport layer (ETL) are sequentially stacked.

The charge generating layer can supply an electric charge to the first stack and the second stack. The charge generating layer can include an N-type charge generating layer for supplying an electron to the first stack and a P-type charge generating layer for supplying a hole to the second stack. The N-type charge generating layer can include a metal material as a dopant.

The second stack can be provided on the first stack and can be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack can be arranged all over the plurality of subpixels SP. The organic light emitting layer 116, according to another example, can be provided in a three-stacked structure or a four-stacked structure, depending on the number of stacks stacked.

The cathode electrode 117 can be formed on the organic light emitting layer 116. The opposing electrode 117 can be disposed in the light emission area EA and the non-light emission area NEA. The cathode electrode 117 according to one example can include a metal material. The cathode electrode 117 can reflect the light emitted from the organic light emitting layer 116 in the plurality of subpixels SP toward the lower surface of the substrate 110. Therefore, the display apparatus 100 according to one embodiment of the present disclosure can be implemented as a bottom emission type display apparatus.

Since the display device 100 according to one embodiment of the present disclosure is bottom-emission type and requires light emitted by the organic light emission layer 116 to be reflected toward the substrate 110, the cathode electrode 117 can be made of a highly reflective metallic material. The cathode electrode 117 according to one embodiment can be formed of a metal material having high reflectance, such as a stacked structure (Ti/Al/Ti) of aluminum and titanium, a stacked structure (ITO/Al/ITO) of aluminum and ITO, an Ag alloy, and a stacked structure (ITO/Ag alloy/ITO) of Ag alloy and ITO. The Ag alloy can be an alloy such as silver (Ag), palladium (Pd), and copper (Cu). Such cathode electrodes 117 can be referred in terms of second electrodes, a reflective electrode, an opposing electrode.

As another example, when the display device 100 according to one embodiment of the present disclosure is top-emission type, the cathode electrode 117 can be formed of a transparent conductive material TCO series such as ITO, IZO, or a semi-transmissive conductive material TMCM series such as magnesium Mg, silver Ag, or an alloy of magnesium Mg and silver Ag that is capable of transmitting light.

The filling layer 118 is formed on the cathode electrodes 117. The filling layer 118 serves to prevent oxygen or moisture from penetrating into the organic light emitting layer 116 and the cathode electrodes 117. To this end, the filling layer 118 can be configured to include a getter capable of absorbing oxygen or moisture. Alternatively, the filling layer 118 can comprise a plurality of layers including at least one inorganic film and at least one organic film.

On the other hand, as shown in FIG. 3, the filling layer 118 can be disposed not only in the light emission area EA but also in the non-light emission area NEA. The filling layer 118 can be disposed between the cathode electrodes 117 and the opposing substrate 200.

On the other hand, the display device 100 according to one embodiment of the present disclosure can be configured such that the share connection line SCL (or the first share connection line SCL1) connecting circuit areas of two adjacent sub-pixels SP (the two sub-pixels SP are configured to emit light of the same color) partially overlaps the light emission area EA (or the first light emission area EA1). Thus, as shown in FIG. 4, the share connection line SCL (or the first share connection line SCL1) can partially overlap the light emitting element layer E in the light emission area EA. The share connection line SCL (or first share connection line SCL1) can be made of the same material as the active layer, for example, transparent wiring including IGZO. Thus, even if the share connection line SCL (or the first share connection line SCL1) partially overlaps the light emission area EA, it cannot be visible to the user. However, it is not necessary to be limited thereto, and depending on the circuit design, the share connection line SCL (or the first share connection line SCL1) may not overlap the light emission area.

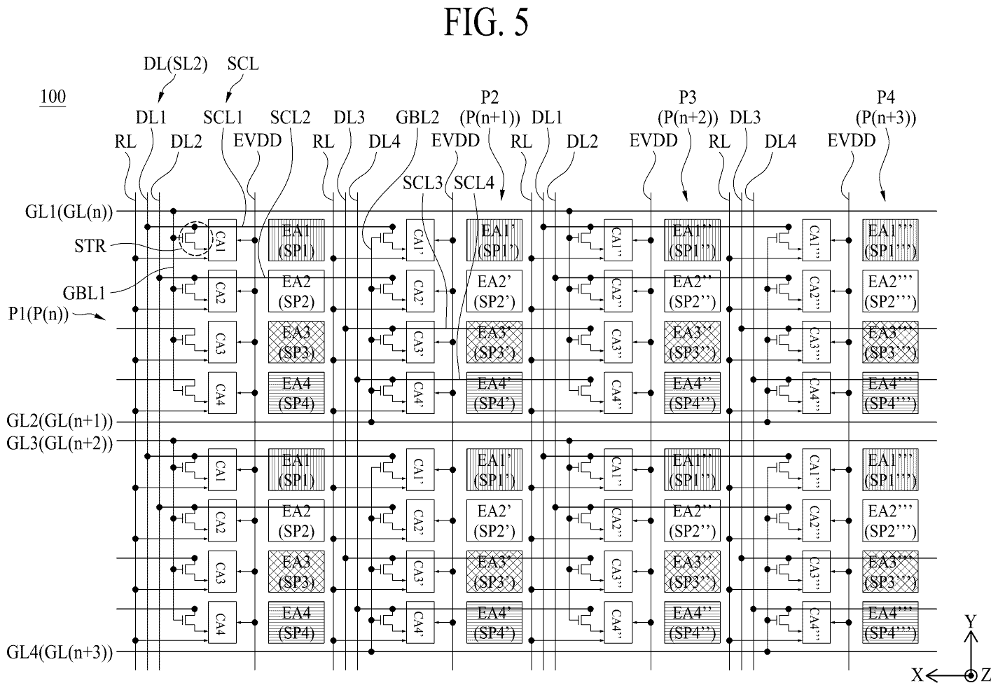

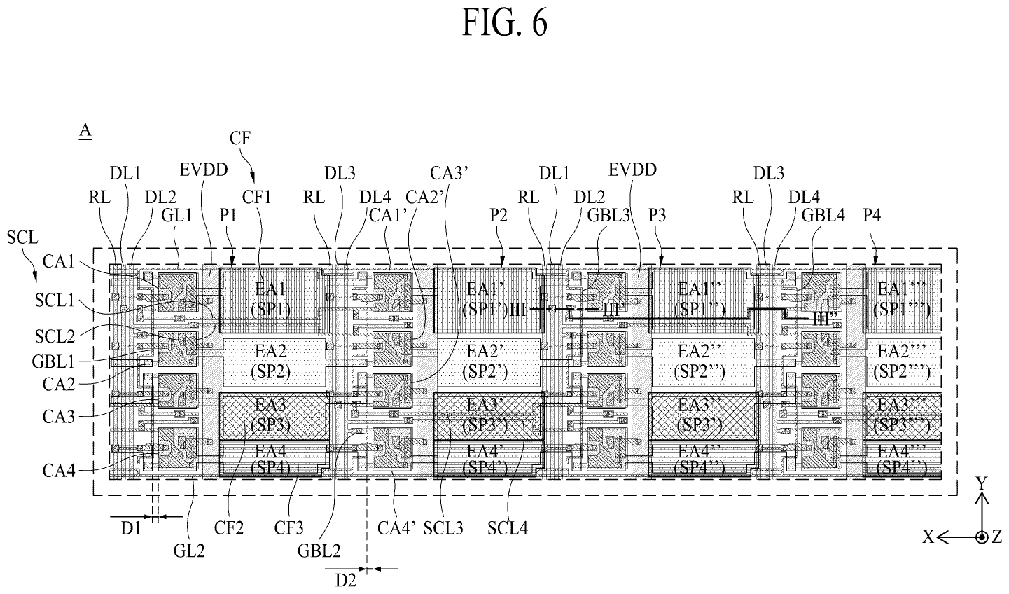

Referring now to FIGS. 5 and 6, a plurality of pixels P and wiring arrangements will be described.

FIG. 5 is a schematic partial plan view illustrating a plurality of pixels including scan transistors of a display device according to one embodiment of the present disclosure, and FIG. 6 is an enlarged plan view of portion A shown in FIG. 1.

Particularly, FIG. 5 is a drawing for illustrating a structure in which a scan transistor STR is connected to each of a data line DL and a gate line GL in a circuit area CA included in each of the plurality of sub-pixels SP. Thus, FIG. 5 separately illustrates the scan transistor STR in the circuit area CA of the plurality of sub-pixels SP. For example, the scan transistor STR can be a configuration that is included in the circuit area CA.

Referring to FIG. 5, the plurality of gate lines GL can include the first gate line GL1 (or GLn), the second gate line GL2 (or GLn+1), the third gate line GL3 (or GLn+2), and the fourth gate line GL4 (or GLn+3). The first gate line GL1 can be disposed to extend in the first direction (X-axis direction) intersecting with the first data line DL1 and can be disposed adjacent to the first sub-pixel SP1 (or upper side of the first sub-pixel SP1 with reference to FIG. 5). The first gate line GL1 can be connected to the first gate branch line GBL1.

The first gate branch line GBL1 according to one example is to connect the first gate line GL1 to the scan transistor STR of each of the first to fourth sub-pixels SP1, SP2, SP3, and SP4 of the first pixel P1. For example, the first gate branch line GBL1 can be disposed between the circuit areas CA2, CA3, and CA4 of each of the second sub-pixel SP2, the third sub-pixel SP3, and the fourth sub-pixel SP4, the first circuit area CA1 of the first sub-pixel SP1, and the first data line DL1 thereby being connected to the scan transistor STR of each of the first to fourth sub-pixels SP1, SP2, SP3, SP4. Thus, the first gate branch line GBL1 can apply a gate signal of the first gate line GL1 to the scan transistor STR of each of the first to fourth sub-pixels SP1, SP2, SP3, and SP4. For example, the first gate branch line GBL1 can extend in the second direction (Y-axis direction) between the circuit areas CA2, CA3, and CA4 of each of the second sub-pixel SP2, the third sub-pixel SP3, and the fourth sub-pixel SP4, the first circuit area CA1 of the first sub-pixel SP1, and the first data line DL1.

On the other hand, as shown in FIG. 5, the first gate branch line GBL1 is disposed to extend in the second direction (Y-axis direction) between the circuit areas CA2, CA3, and CA4 of each of the second sub-pixel SP2, the third sub-pixel SP3, and the fourth sub-pixel SP4, the first circuit area CA1 of the first sub-pixel SP1, and the first data line DL1. Thus, the circuit areas CA2, CA3, and CA4 of each of the second sub-pixel SP2, the third sub-pixel SP3, and the fourth sub-pixel SP4 and the first circuit area CA1 of the first sub-pixel SP1 can be disposed in the same direction. For example, the first gate branch line GBL1 can be disposed in the second direction (Y-axis direction) along with the circuit areas CA2, CA3, and CA4 of each of the second sub-pixel SP2, the third sub-pixel SP3, and the fourth sub-pixel SP4, and the first circuit area CAL of the first sub-pixel SP1.

The first gate branch line GBL1 according to an example can be spaced apart by the same distance from the circuit areas CA2, CA3, and CA4 of each of the second sub-pixel SP2, the third sub-pixel SP3, and the fourth sub-pixel SP4 and the first circuit area CA1 of the first sub-pixel SP1. For example, as shown in FIG. 6, the first gate branch line GBL1 can be spaced apart by a first distance D1 from each of the circuit areas CA2, CA3, CA4 of each of the second sub-pixel SP2, the third sub-pixel SP3, and the fourth sub-pixel SP4 and the first circuit area CA1 of the first sub-pixel SP1. Here, the circuit areas CA1, CA2, CA3, and CA4 of each of the first to fourth sub-pixels SP1, SP2, SP3, and SP4 can refer to gate nodes of a drive transistor included in the circuit areas CA1, CA2, CA3, and CA4 of each of the first to fourth sub-pixels SP1, SP2, SP3, and SP4.

In the case of a general display device, in order to connect two sub-pixels emitting different colors to one data line, the circuit area of each sub-pixel have a structure in which the circuit area of each sub-pixel is inverted up and down or left and right from each other. Thus, in a general display device, the gate line and the circuit area of each of the two sub-pixels (e.g., the gate nodes of the driving transistors) can be spaced apart by different distances due to process deviations. In this case, a parasitic capacitance (or size) can be small when the distance between the gate line and the circuit area is close, and a parasitic capacitance (or size) can be large when the distance between the gate line and the circuit area is farther apart, thereby generating a parasitic cap deviation. Accordingly, in a general display device, a gate signal connected to a one data line and applied to each of two sub-pixels emitting different colors is interfered with a parasitic cap having different capacities (or sizes), resulting in a signal deviation, thereby degrading the image quality.

In contrast, in the display device 100 according to one embodiment of the present disclosure, the first gate branch line GBL1 is disposed in the same direction as the circuit areas CA2, CA3, and CA4 of each of the second sub-pixel SP2, the third sub-pixel SP3, and the fourth sub-pixel SP4, and the first circuit area CA1 of the first sub-pixel SP1. Thus, even if a process deviation occurs, the first gate branch line GBL1 can be spaced apart by the same distance away from or close to each of the circuit areas CA2, CA3, and CA4 of each of the second sub-pixel SP2, the third sub-pixel SP3, and the fourth sub-pixel SP4, and the first circuit area CA1 of the first sub-pixel SP1. Therefore, deviations in the gate signals of each of the first to fourth sub-pixels SP1, SP2, SP3, and SP4 cannot occur and image quality degradation can be prevented.

As a result, in the display device 100 according to one embodiment of the present disclosure, two sub-pixels (e.g., the first sub-pixel SP1 and the another first sub-pixel SP1′) emitting light with the same color and disposed adjacent to each other, share one data line (e.g., the first data line DL1) and the circuit area of each of the two sub-pixels is spaced apart by the same distance from the gate branch line (e.g., the first gate branch line GBL1), thus the number of drive ICs can be reduced as well as image quality degradation can be prevented.

A second data line DL2 included in a plurality of data lines DL can be disposed between the circuit areas CA2, CA3, and CA4 of each of the second sub-pixel SP2, the third sub-pixel SP3, and the fourth sub-pixel SP4 and the first data line DL1. The second data line DL2 can also be disposed between the first circuit area CA1 of the first sub-pixel SP1 and the first data line DL1. Thus, the second data line DL2 can be disposed to extend in the second direction (Y-axis direction) between the circuit areas CA1, CA2, CA3, and CA4 of each of the first to fourth sub-pixels SP1, SP2, SP3, and SP4 and the first data line DL1.

The display device 100 according to one embodiment of the present disclosure can further include the second share connection line SCL2. The second share connection line SCL2 is to connect the second data line DL2 to the circuit area CA2 of the second sub-pixel SP2 of the first pixel P1 and the circuit area CA2′ of the another second sub-pixel SP2′ of the second pixel P2, respectively.

In order to connect each of the circuit area CA2 of the second sub-pixel SP2 and the circuit area CA2′ of the another second sub-pixel SP2, the second share connection line SCL2 according to an example can partially overlap the light emission area EA2 of the second sub-pixel SP2. However, it is not limited thereto, when a circuit area of one sub-pixel SP and a circuit area of another sub-pixel SP are connectable, the second share connection line SCL2 can partially overlap a light emission area of another first sub-pixel SP (e.g., a light emission area (or second light emission area) of another second sub-pixel SP of another pixel to the left of the first pixel P1). Thus, in the display device 100 according to one embodiment of the present disclosure, the second share connection line SCL2 can partially overlap the light emission area EA2 of the second sub-pixel SP2 or the second light emission area of another second sub-pixel. In FIG. 5, the second share connection line SCL2 is shown partially overlapping the light emission area EA2 of the second sub-pixel SP2, but is not limited thereto, and as shown in FIG. 6, the second share connection line SCL2 can partially overlap the light emission area EA1 of the first sub-pixel SP1. In this case, the light emission area EA1 of the first sub-pixel SP1 can overlap both a portion of the first share connection line SCL1 and a portion of the second share connection line SCL2.

As a result, the display device 100 according to one embodiment of the present disclosure can have a structural feature in which the share connection line SCL partially overlaps the light emission area of any one of the two adjacent sub-pixels SPs in order to connect one data line to a circuit area of each of the two adjacent sub-pixels SPs emitting light with the same color. However, it is not necessarily limited thereto, and depending on the circuit design, the share connection line SCL may not partially overlap the light emission area.

Meanwhile, the first gate branch line GBL1 can be disposed to extend in the second direction (Y-axis direction) between the circuit areas CA2, CA3, and CA4 of each of the second sub-pixel SP2, the third sub-pixel SP3, and the fourth sub-pixel SP4, and the first circuit area CA1 of the first sub-pixel SP1, and the first data line DL1. Accordingly, the first gate branch line GBL1 can intersect with the first share connection line SCL1 and the second share connection line SCL2.

The display device 100 according to one embodiment of the present disclosure can include a third data line DL3 and the third share connection line SCL3. The third data line DL3 can extend in the second direction (Y-axis direction) between a first sub-pixel SP1 of the first pixel P1 and the another first sub-pixel SP1′ of the second pixel P2. The third share connection line SCL3 can connect the third data line DL3 to the circuit area CA3′ of the another third sub-pixel SP3′ of the second pixel P2 and the circuit area CA3″ of the another third sub-pixel SP3″ of the third pixel P3, respectively. Here, the another third sub-pixel SP3″ of the third pixel P3 can be configured to emit light with the same color (e.g., blue) as the another third sub-pixel SP3′ of the second pixel P2.

In order to connect each of the circuit area CA3′ of the another third sub-pixel SP3′ of the second pixel P2 and the circuit area CA3″ of the another third sub-pixel SP3″ of the third pixel P3, the third share connection line SCL3 according to an example can partially overlap the light emission area EA3′ of the another third sub-pixel SP3′ of the second pixel P2. However, it is not limited thereto, when the circuit area of one sub-pixel SP and the circuit area of another sub-pixel SP are connectable, the third share connection line SCL3 can partially overlap the light emission area EA3 of another third sub-pixel SP3 (e.g., the light emission area EA3 of the another third sub-pixel SP3 of the first pixel P1 to the left of the second pixel P2). Thus, the display device 100 according to one embodiment of the present disclosure can have the third share connection line SCL3 partially overlapping the light emission area EA3′ of the another third sub-pixel SP3′ or the light emission area EA3 of the third sub-pixel SP3.

As a result, the display device 100 according to one embodiment of the present disclosure can have a structural feature in which the share connection line SCL partially overlaps the light emission area of any one of the two adjacent sub-pixels SPs in order to connect one data line to a circuit area of each of the two adjacent sub-pixels SPs emitting light with the same color. However, it is not necessarily limited thereto, and depending on the circuit design, the share connection line SCL may not partially overlap the light emission area.

On the other hand, the third share connection line SCL3 can be connected to the third data line DL3 and extend in the first direction (X-axis direction). Accordingly, a portion of the third share connection line SCL3 can overlap a portion of the second share connection line SCL2 (or a portion of the first share connection line SCL1) in the second direction (Y-axis direction). Here, a portion of the third share connection line SCL3 can mean a left portion of the third share connection line SCL3 with respect to FIG. 5, and a portion of the second share connection line SCL2 (or a portion of the first share connection line SCL1) can mean a right portion of the second share connection line SCL2 (or a right portion of the first share connection line SCL1) with respect to FIG. 5.

The display device 100 according to one embodiment of the present disclosure can include a fourth data line DLA and the fourth share connection line SCL4. The fourth data line DLA can be disposed between the circuit areas CA2′, CA3′ of each of the another second sub-pixel SP2′ and the another third sub-pixel SP3′ of the second pixel P2, and the third data line DL3. The fourth share connection line SCL4 can connect the fourth data line DL4 to the circuit area CA4′ of the another fourth sub-pixel SP4′ of the second pixel P2 and the circuit area CA4″ of the another fourth sub-pixel SP4″ of the third pixel P3, respectively. Here, the another fourth sub-pixel SP4″ of the third pixel P3 can be configured to emit light with the same color (e.g., green) as the another fourth sub-pixel SP4′ of the second pixel P2.

In order to connect each of the circuit area CA4′ of the another fourth sub-pixel SP4′ of the second pixel P2 and the circuit area CA4″ of another fourth sub-pixel SP4″ of the third pixel P3, the fourth share connection line SCL4 according to an example can partially overlap the light emission area EA4′ of the another fourth sub-pixel SP4′ of the second pixel P2. However, it is not limited thereto, when a circuit area of one sub-pixel SP and a circuit area of another sub-pixel SP are connectable, the fourth share connection line SCLA can partially overlap the light emission area of another sub-pixel SP (e.g., the light emission area EA4 of the another fourth sub-pixel SP4 of the first pixel P1 to the left of the second pixel P2). Thus, the display device 100 according to one embodiment of the present disclosure can have the fourth share connection line

SCL4 partially overlapping the light emission area EA4′ of the another fourth sub-pixel SP4 or the light emission area EA4 of the fourth sub-pixel SP4.

As a result, the display device 100 according to one embodiment of the present disclosure can have a structural feature in which the share connection line SCL partially overlaps the light emission area of any one of the two adjacent sub-pixels SPs in order to connect one data line to circuit area of each of the two adjacent sub-pixels SPs emitting light with the same color. However, it is not necessarily limited thereto, and depending on the circuit design, the share connection line SCL may not partially overlap the light emission area.

Meanwhile, the second gate line GL2 can disposed to extend in the first direction (X-axis direction) intersecting with the fourth data line DL4 and can be disposed adjacent to the another fourth sub-pixel SP4′ of the second pixel P2 (or the lower side of the another fourth sub-pixel SP4′ with reference to FIG. 5). The second gate line GL2 can be connected to the second gate branch line GBL2.

The second gate branch line GBL2 according to one example is to connect the second gate line GL2 to the scan transistor STR of each of the another first to fourth sub-pixels SP1′, SP2′, SP3′, and SP4′ of the second pixel P2. For example, the second gate branch line GBL2 can be disposed between the circuit area CA2′, CA3′, and CA4′ of each of the another second sub-pixel SP2′, the another third sub-pixel SP3′, and the another fourth sub-pixel SP4′, the second circuit area CA1′ of the another first sub-pixel SP1′, and the fourth data line DL4, and be connected to the scan transistor STR of each of the another first to fourth sub-pixels SP1′, SP2′, SP3′, and SP4′. Thus, the second gate branch line GBL2 can apply a gate signal of the second gate line GL2 to the scan transistor STR of each of the another first to fourth sub-pixels SP1′, SP2′, SP3′, and SP4′ of the second pixel P2. For example, the second gate branch line GBL2 can extend in the second direction (Y-axis direction) between the circuit areas CA2′, CA3′, and CA4′ of each of the another second sub-pixel SP2′, the another third sub-pixel SP3′, and the another fourth sub-pixel SP4′, and the second circuit area CA1′ of the another first sub-pixel SP1′, and the fourth data line DL4.

On the other hand, the second gate branch line GBL2 is disposed to extend in the second direction (Y-axis direction) between the circuit areas CA2′, CA3′, and CA4′ of each of the another second sub-pixel SP2′, the another third sub-pixel SP3′, and the another fourth sub-pixel SP4′ of the second pixel P2, the second circuit area CA1′ of the another first sub-pixel SP1′, and the fourth data line DL4. Thus, the circuit areas CA2′, CA3′, and CA4′ of each of the another second sub-pixel SP2′, the another third sub-pixel SP3′, and the another fourth sub-pixel SP4′ of the second pixel P2 and the second circuit area CA1′ of the another first sub-pixel SP1′ are disposed in the same direction. For example, the second gate branch line GBL2 can be disposed in the second direction (Y-axis direction) along with the circuit areas CA2′, CA3′, and CA4′ of each of the another second sub-pixel SP2′, the another third sub-pixel SP3′, the another fourth sub-pixel SP4′ of the second pixel P2, and the second circuit area CA1′ of the another first sub-pixel SP1′.

The second gate branch line GBL2 according to an example can be spaced apart by the same distance from the circuit areas CA2′, CA3′, and CA4′ of each of the another second sub-pixel SP2′, the another third sub-pixel SP3′, and the another fourth sub-pixel SP4′ of the second pixel P2 and the second circuit area CA1′ of the another first sub-pixel SP1′. For example, as shown in FIG. 6, the second gate branch line GBL2 can be spaced apart by a second distance D2 from each of the circuit areas CA2′, CA3′, CA4′ of each of the another second sub-pixel SP2′, the another third sub-pixel SP3′, and the another fourth sub-pixel SP4′ of the second pixel P2 and the second circuit area CA1′ of the another first sub-pixel SP1′. Here, the circuit areas CA1′, CA2′, CA3′, and CA4′ of each of the another first to fourth sub-pixels SP1′, SP2′, SP3′, and SP4′ of the second pixel P2 can refer to gate nodes of a drive transistor included in the circuit areas CA1′, CA2′, CA3′, and CA4′ of each of the another first to fourth sub-pixels SP1′, SP2′, SP3′, and SP4′.

Accordingly, the display device 100 according to one embodiment of the present disclosure has the second gate branch line GBL2 spaced apart in the same direction as the circuit areas CA2′, CA3′, and CA4′ of each of the another second sub-pixel SP2′, the another third sub-pixel SP3′, the another fourth sub-pixel SP4′ of the second pixel P2, and the second circuit area CA1′ of the another first sub-pixel SP1′. Thus, even if a process deviation occurs, the second gate branch line GBL2 can be space apart by the same distance away from or close to each of the circuit areas CA2′, CA3′, and CA4′ of each of the another second sub-pixel SP2′, the another third sub-pixel SP3′, the another fourth sub-pixel SP4′ of the second pixel P2 and the second circuit area CA1′ of the another first sub-pixel SP1′. Therefore, deviations in the gate signals of each of the first to fourth sub-pixels SP1, SP2, SP3, and SP4 do not occur and image quality degradation is prevented.

As a result, in the display device 100 according to one embodiment of the present disclosure, two sub-pixels (e.g., the third sub-pixel SP3 and the another third sub-pixel SP3′) emitting light with the same color and disposed adjacent to each other, share one data line (e.g., the third data line DL3) and the circuit area of each of the two sub-pixels is spaced apart by the same distance from the gate branch line (e.g., a second gate branch line GBL2), thus the number of drive ICs can be reduced as well as image quality degradation can be prevented.

Meanwhile, the second gate branch line GBL2 can be disposed to extend in the second direction (Y-axis direction) between the circuit areas CA2′, CA3′, and CA4′ of each of the another second sub-pixel SP2′, the another third sub-pixel SP3′, and the another fourth sub-pixel SP4′ of the second pixel P2, and the second circuit area CA1′ of the another first sub-pixel SP1′, and the fourth data line DL4. Accordingly, the second gate branch line GBL2 can intersect with the third share connection line SCL3 and the fourth share connection line SCL4.

The display device 100 according to one embodiment of the present disclosure can further include the third gate branch line GBL3 connected to the first gate line GL1 and disposed between the second pixel P2 and the third pixel P3, and a fourth gate branch line GBL4 connected to the second gate line GL2 and disposed between the third pixel P3 and the fourth pixel P4.

As a result, in the display device 100 according to one embodiment of the present disclosure, the gate of the scan transistor STR of each of the first pixel P1 (or the first pixel Pn) and the third pixel P3 (or the third pixel Pn+2) can be connected to the first gate line GL1 (or the first gate line GLn), the gate of the scan transistor STR of each of the second pixel P2 (or the second pixel Pn+1) and the fourth pixel P4 (or the fourth pixel Pn+3) can be connected to the second gate line GL2 (or the second gate line GLn+1).

In addition, in the display device 100 according to one embodiment of the present disclosure, each of the another first sub-pixel SP1′ and the another second sub-pixel SP2′ of the second pixel P2 (or the second pixel Pn+1) can share a data line (or the first data line DL1 and the second data line DL2) with each of the first sub-pixel SP1 and the second sub-pixel SP2 of the first pixel P1 (or the first pixel Pn). Further, each of the another third sub-pixel SP3′ and the another fourth sub-pixel SP4′ of the second pixel P2 (or the second pixel Pn+1) can share a data line (or the third data line DL3 and the fourth data line DL4) with each of the another third sub-pixel SP3″ and the another fourth sub-pixel SP4″ of the third pixel P3 (or the third pixel Pn+2).

Referring now to FIGS. 6 to 8, cross-sectional structures of the share connection line SCL (or the first share connection line SCL1) and the gate branch lines are described.

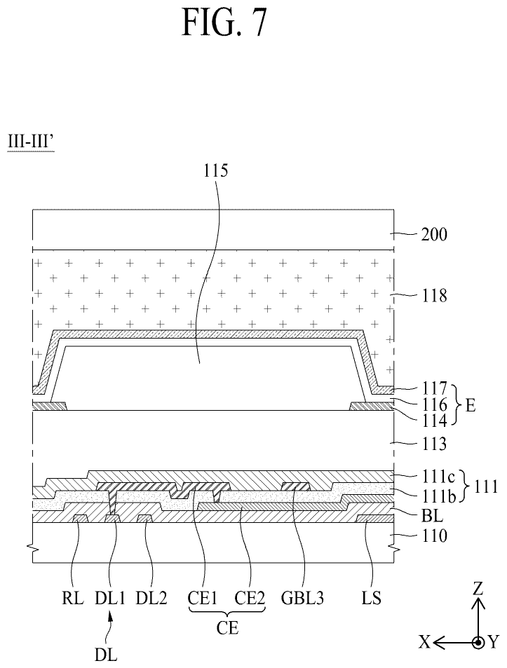

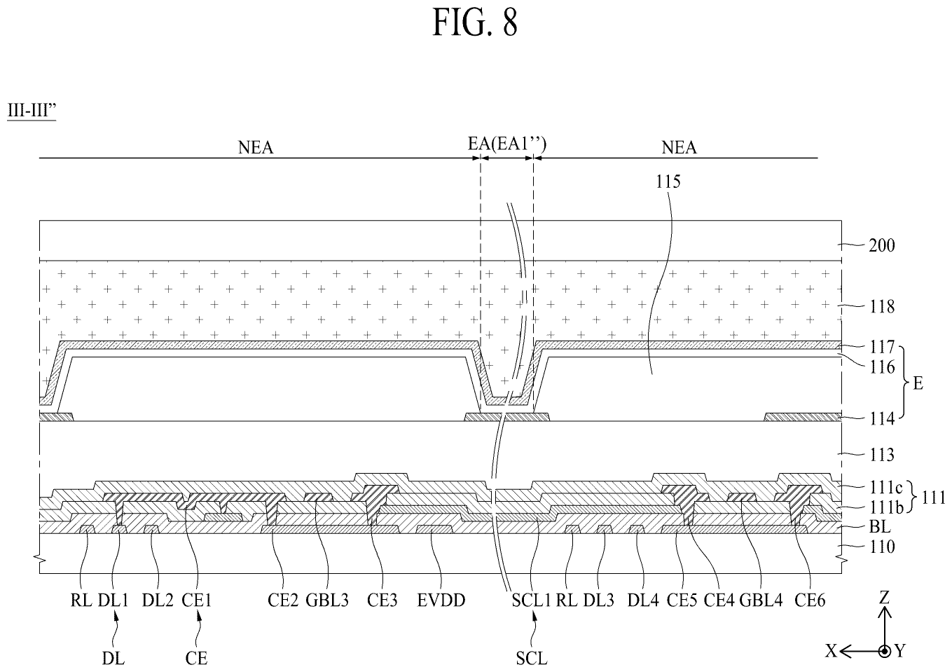

FIG. 7 is a schematic cross-sectional view of the line I-II′ shown in FIG. 6 and FIG. 8 is a schematic cross-sectional view of the line II-III″ shown in FIG. 6. Particularly, FIGS. 7 and 8 are illustrated using the third pixel P3 and the fourth pixel P4 as examples, and the same structure can be applied to the first pixel P1 and the second pixel P2.

First, referring to FIG. 6, the share connection line SCL (or the first share connection line SCL1) can be connected to the first data line DL1 and can be connected to the circuit area of another first sub-pixel SP1″ of the third pixel P3 in the first direction (X-axis direction). Further, the share connection line SCL (or the first share connection line SCL1) can be connected to the first data line DL1 and can be connected to the circuit area of the another first sub-pixel SP1″′ of the fourth pixel P4 across the light emission area EA1″ of the another first sub-pixel SP1″ of the third pixel P3 in the first direction (X-axis direction). The share connection line SCL (or the first share connection line SCL1) can be connected to each of the first data line DL1, the circuit area of the another first sub-pixel SP1″ of the third pixel P3, and the circuit area of another fourth sub-pixel SP1″ of the fourth pixel P4 via a plurality of connection electrodes CE.

Referring to FIG. 7, a first connection electrode CE1 can be connected to the first data line DL1. The first connection electrode CE1 can be disposed between the interlayer insulation layer 111b and the passivation layer 111c, and one side of the first connection electrode CE1 can contact the upper surface of the first data line DL1 through a contact hole penetrating the interlayer insulation layer 111b and the buffer layer BL. The other side of the first connection electrode CE1 can be contacted to the upper surface of one side of a second connection electrode CE2 through a contact hole penetrating the interlayer insulation layer 111b. The second connection electrode CE2 can be disposed between the buffer layer BL and the interlayer insulation layer 111b. Although not shown, the second connection electrode CE2 can extend in the first direction (the X-axis direction) and can be connected to the circuit area of the another first sub-pixel SP1″ of the third pixel P3. Thus, the circuit area of the another first sub-pixel SP1″ of the third pixel P3 can be connected to the first data line DL1 via the first connection electrode CE1 and the second connection electrode CE2, and can receive a data voltage from the first data line DL1. The third gate branch line GBL3 shown in FIG. 7 can be disposed on the same layer as the first connection electrode CE1. The shield layer LS shown in FIG. 7 can be for protecting a thin film transistor disposed in the circuit area of the another first sub-pixel SP1″ of the third pixel P3.

Referring to FIG. 8, the other side of the second connection electrode CE2 can be connected to the share connection line SCL (or the first share connection line SCL1) via a third connection electrode CE3. The third connection electrode CE3 can be disposed between the interlayer insulation layer 111b and the passivation layer 111c, and can contact the upper surface of the other side of the second connection electrode CE2 through a contact hole penetrating the interlayer insulation layer 111b and the buffer layer BL.

The share connection line SCL (or the first share connection line SCL1) can be disposed between the interlayer insulation layer 111b and the buffer layer BL. One side of the share connection line SCL (or the first share connection line SCL1) can contact one side of the third connection electrode CE3. Such the share connection line SCL (or first share connection line SCL1) can extend in the first direction (X-axis direction) to be connected to the circuit area of the another first sub-pixel SP1″ of the fourth pixel P4. Here, the share connection line SCL (or the first share connection line SCL1) can partially overlap the light emission area EA1″ of the another first sub-pixel SP1″ of the third pixel P3. Since the share connection line SCL (or the first share connection line SCL1) is disposed between the interlayer insulation layer 111b and the buffer layer BL, and can be disposed on the reference line RL, the third data line DL3, and the fourth data line DLA that are disposed between the buffer layer BL and the substrate 110. Thus, on a plane, the share connection line SCL (or the first share connection line SCL1) can intersect with the reference line RL, the third data line DL3, and the fourth data line DL4 disposed between the third pixel P3 and the fourth pixel P4.

The other side of the share connection line SCL (or the first share connection line SCL1) can contact one side of the third connection electrode CE3. The fourth connection electrode CE4 can be disposed between the interlayer insulation layer 111b and the passivation layer 111c, and can contact the upper surface of one side of the fifth connection electrode CE5 through a contact hole penetrating the interlayer insulation layer 111b and the buffer layer BL. The fifth connection electrode CE5 can be disposed between the buffer layer BL and the substrate 110 and can extend in the first direction (X-axis direction). The other side of the fifth connection electrode CE5 can be connected to a sixth connection electrode CE6. The sixth connection electrode CE6 can be disposed between the interlayer insulation layer 111b and the passivation layer 111c, and can contact the upper surface of the other side of the fifth connection electrode CE5 through a contact hole penetrating the interlayer insulation layer 111b and the buffer layer BL. The circuit area of the another first sub-pixel SP1″ of the fourth pixel P4 can be connected to the sixth connection electrode CE6 through another connection electrode. Thus, the circuit area of the another first sub-pixel SP1″ of the fourth pixel P4 can be connected to the first data line disposed between the second pixel P2 and the third pixel P3 through the first to sixth connection electrodes, another connection electrode, and the share connection line SCL (or the first share connection line SCL1) to be applied with a data voltage from the first data line DL1.

Therefore, in the display device 100 according to one embodiment of the present disclosure, two adjacent sub-pixels emitting light with the same color can be connected to one data line via the share connection line, and can be applied with the same driving voltage, thus data swing cannot occur, thereby preventing heating of the drive IC.

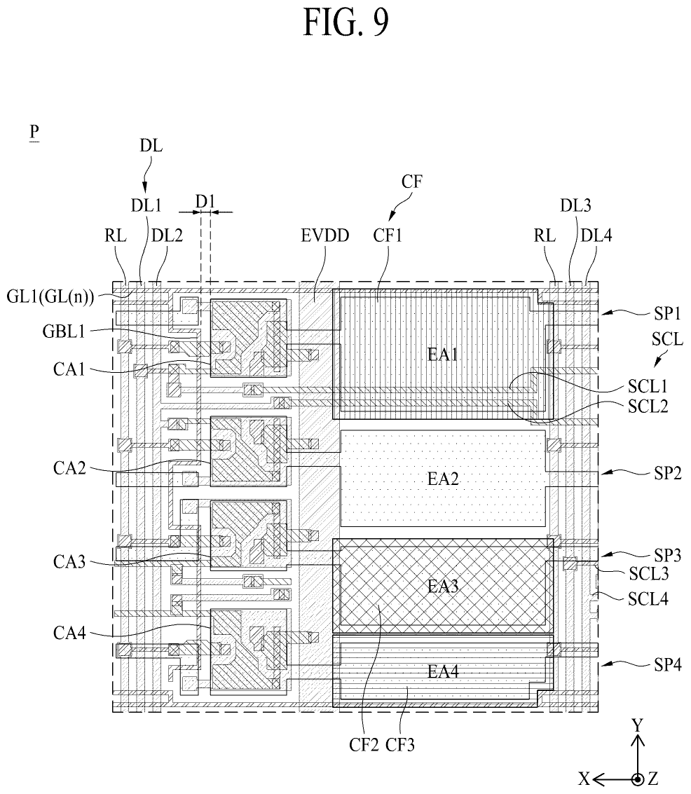

Hereinafter, with reference to FIG. 9, one pixel P of the display device 100 according to one embodiment of the present disclosure will be described in detail.

FIG. 9 is a schematic plan view of one pixel shown in FIG. 6.

Referring to FIG. 9, each of the first sub-pixel SP1, the second sub-pixel SP2, the third sub-pixel SP3, and the fourth sub-pixel SP4 of the first pixel P1 can be disposed adjacent to each other in the second direction (Y-axis direction). The first sub-pixel SP1 can include the light emission area EA1 (or the first light emission area EA1) and the circuit area CA1 (or the first circuit area CA1) disposed adjacent to each other in the first direction (X-axis direction). The second sub-pixel SP2 can include the light emission area EA2 and the circuit area CA2 disposed adjacent in the first direction (X-axis direction). The third sub-pixel SP3 can include the light emission area EA3 and the circuit area CA3 disposed adjacent in the first direction (X-axis direction). The fourth sub-pixel SP4 can include the light emission area EA4 and the circuit area CA4 disposed adjacent in the first direction (X-axis direction).

The first gate line GL1 can be disposed adjacent to the upper side of the first sub-pixel SP1 and extending in the first direction (X-axis direction). The reference line RL, the first data line DL1, and the second data line DL2 can extend in the second direction (Y-axis direction) to intersect with the first gate line GL1. The first gate branch line GBL1 can be connected to the first gate line GL1, and can be disposed to extend in the second direction (Y-axis direction) between the second data line DL2 and the circuit areas CA1, CA2, CA3, and CA4 of each of the first to fourth sub-pixels. Accordingly, the first gate branch line GBL1 can be spaced apart by the same distance (e.g., the first distance D1) from the circuit areas CA1, CA2, CA3, and CA4 of each of the first to fourth sub-pixels. Therefore, in the display device 100 according to one embodiment of the present disclosure, the first gate branch line GBL1 can be spaced apart by the same distance away from or close to each of the circuit areas CA1, CA2, CA3, and CA4 of each of the first to fourth sub-pixels SP1, SP2, SP3, SP4 even if a process deviation occurs, thus a deviation in the gate signals of each of the first to fourth sub-pixels SP1, SP2, SP3, and SP4 cannot occur and image quality degradation can be prevented.

The first share connection line SCL1 can be connected to the first data line DL1 and extend in the first direction (X-axis direction) toward the another first sub-pixel SP1′ of the second pixel P2. The second share connection line SCL2 can be connected to the second data line DL2 and can extend in the first direction (X-axis direction) toward the another second sub-pixel SP2′ of the second pixel P2. The second share connection line SCL2 can be spaced apart from the first share connection line SCL1. Since each of the first share connection line SCL1 and the second share connection line SCL2 is disposed in the first direction (X-axis direction), and the first gate branch line GBL1 is disposed in the second direction (Y-axis direction), each of the first share connection line SCL1 and the second share connection line SCL2 can intersect with the first gate branch line GBL1.

Each of the first share connection line SCL1 and the second share connection line SCL2 can partially overlap the light emission area EA1 (or first light emission area EA1) of the first sub-pixel SP1. Each of the first share connection line SCL1 and the second share connection line SCL2 can be provided with transparent wiring such as IGZO, so that even if they overlap with the light emission area EA1 (or the first light emission area EA1), they cannot be visible to a user. The first share connection line SCL1 can be connected to the circuit area of the another first sub-pixel SP1′ of the second pixel P2 across the light emission area EA1 (or the first light emission area EA1). The second share connection line SCL2 can be connected to the circuit area of each of the another second sub-pixels SP2′ of the second pixel P2 across the light emission area EA1 (or the first light emission area EA1). Accordingly, each of the first sub-pixel SP1 of the first pixel P1 and the another first sub-pixels SP1′ of the second pixel P2 can be connected to the first data line DL1 via the first share connection line SCL1, thus the same driving voltage can be applied from the first data line DL1. Further, each of the second sub-pixel SP2 of the first pixel Pl and the another second sub-pixel SP2′ of the second pixel P2 can be connected to the second data line DL2 via the second share connection line SCL2, thus the same driving voltage can be applied from the second data line DL2.

Meanwhile, each of the first share connection line SCL1 and the second share connection line SCL2 is connected to each of the circuit area of the another first sub-pixel SP1′ of the second pixel P2 and the circuit area of the another second sub-pixel SP2′ of the second pixel P2 across the light emission area EA1 (or the first light emission area EA1), thus can intersect with each of the reference line RL, the third data line DL3, and the fourth data line DL4 disposed between the first pixel P1 and the second pixel P2. The third share connection line SCL3 can be connected to the third data line DL3 and can extend in the first direction (the X-axis direction). The fourth share connection line SCL4 can be connected to the fourth data line DL4 and can extend in the first direction (X-axis direction). The third share connection line SCL3 can connect the circuit area of another third sub-pixel SP3′ of the second pixel P2 and the circuit area of another third sub-pixel SP3″ of the third pixel P3. The fourth share connection line SCL4 can connect the circuit area of another fourth sub-pixel SP4′ of the second pixel P2 and the circuit area of another fourth sub-pixel SP4″ of the third pixel P3.

Accordingly, as shown in FIG. 5, the display device 100 according to one embodiment of the present disclosure can be provided with a structure in which the first share connection line SCL1, the second share connection line SCL2, and the third share connection line SCL3 and the fourth share connection line SCL4 are disposed in a zigzag shape in a second direction (Y-axis direction).

Meanwhile, the display device 100 according to one embodiment of the present disclosure is implemented in a bottom-emission type, thus can be configured such that the first color filter CF1 covers the light emission area EA1 (or the first light emission area EA1) of the first sub-pixel SP1, the second color filter CF2 covers the light emission area EA3 of the third sub-pixel SP3, and the third color filter CF3 covers the light emission area EA4 of the fourth sub-pixel SP4. Since the second sub-pixel SP2 emits white light, the color filter cannot be provided. Therefore, the display device 100 according to one embodiment of the present disclosure can be provided with a structure in which the first color filter CF1 does not overlap the circuit area CA1 of the first sub-pixel SP1 (or the first circuit area CA1), the second color filter CF2 does not overlap the circuit area CA3 of the third sub-pixel SP3, and the third color filter CF3 does not overlap the circuit area CA4 of the fourth sub-pixel SP4.

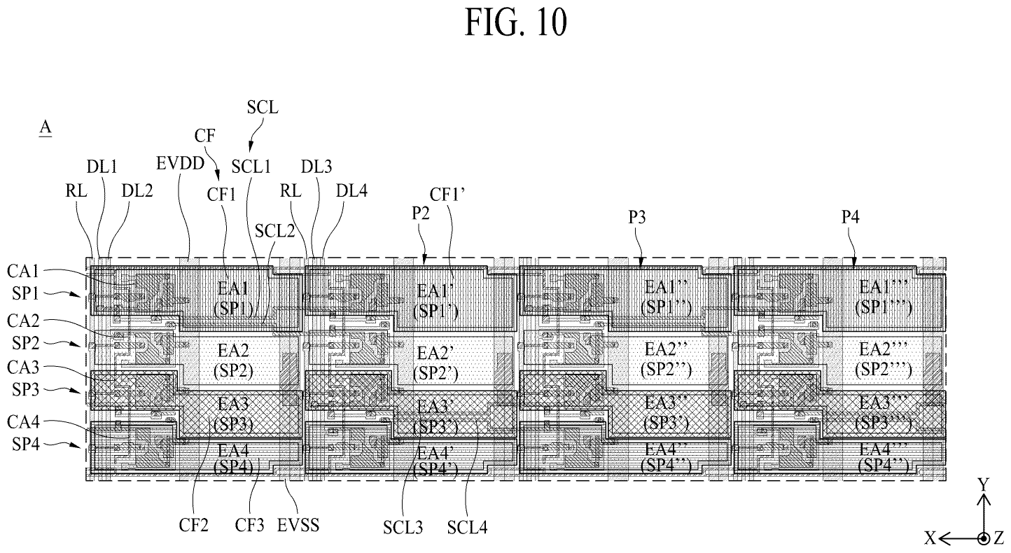

FIG. 10 is a schematic plan view of a display device according to a second embodiment of the present disclosure.

Referring now to FIG. 10, the display device 100 according to the second embodiment of the present disclosure is the same as the display device according to FIG. 1 described above, except that the light emission type is changed to top-emission type, and the disposition area of the color filter CF is changed. Therefore, the same drawing symbols have been assigned to the same configuration, and only the different configurations will be described hereinafter.

The display device according to FIG. 1 is implemented in bottom-emission type, thus can be configured such that the first color filter CF1 covers the light emission area EA1 of the first sub-pixel SP1 and does not overlap the circuit area CA1 (or the first circuit area CA1), the second color filter CF2 covers the light emission area EA3 of the third sub-pixel SP3 and does not overlap the circuit area CA3, and the third color filter CF3 covers the light emission area EA4 of the fourth sub-pixel SP4 and does not overlap the circuit area CA4. Therefore, in the case of the display device according to FIG. 1, the display device can have a structure in which the color filters CF (or the first color filter CF1) of each of the first sub-pixel SP1 of the first pixel P1 and the another first sub-pixel SP1′ of the second pixel P2 is spaced apart from each other with the circuit area interposed therebetween.

In contrast, the display device according to FIG. 10 is implemented in top-emission type, thus can be configured such that the first color filter CF1 covers the circuit area CA1 (or the first circuit area CA1) and the light emission area EA1 (or the first light emission area EA1) of the first sub-pixel SP1, the second color filter CF2 covers the circuit area CA3 and the light emission area EA3 of the third sub-pixel SP3, and the third color filter CF3 covers the circuit area CA4 and the light emission area EA4 of the fourth sub-pixel SP4. The second pixel P2 is configured such that another first color filter CF1′ of the same color as the first color filter CF1 covers the circuit area CA1′ (or second circuit area CA1′) and the light emission area EA1′ (or second light emission area EA1′) of the another first sub-pixel SP1′, the second color filter CF2 (or other second color filter) covers the circuit area CA3′ and the light emission area EA3′ of the another third sub-pixel SP3′, and the third color filter CF3 (or other third color filter) covers the circuit area CA4′ and the light emission area EA4′ of the another fourth sub-pixel SP4′. Thus, the display device 100 according to FIG. 10 can be configured with a larger size (or area) of the light emission area compared to a case where the color filter covers only the light emission area, and therefore, the light emission efficiency can be further improved.

Since the display device according to FIG. 10 is implemented in top-emission type, thus each of the first color filter CF1, the second color filter CF2, and the third color filter CF3 can be larger than each of the first color filter CF1, the second color filter CF2, and the third color filter CF3 of the display device according to FIG. 1. Therefore, the display device 100 according to the second embodiment of the present disclosure can be provided such that the color filters of each of the two adjacent sub-pixels SP emitting light with the same color are divided from or connected to each other. For example, the first color filter CF1 of the first sub-pixel SP1 included in the first pixel P1 can be divided from or connected to from the first color filter CF1′ of the another first sub-pixel SP1′ included in the second pixel P2. Likewise, the second color filter CF2 of the third sub-pixel SP3 included in the first pixel P1 can be divided from or connected to the second color filter CF2 of the another third sub-pixel SP3′ included in the second pixel P2, the third color filter CF3 of the fourth sub-pixel SP4 included in the first pixel P1 can be divided from or connected to the third color filter CF3 of the another fourth sub-pixel SP4′ included in the second pixel P2.

When the color filters of each of the sub-pixels SP emitting light with the same color are connected to each other, the color filters can be provided in the form of a long stripe in the first direction (X-axis direction). In this case, the display device 100 according to the second embodiment of the present disclosure can provide a high quality image to a user, as light leakage may not occur between the sub-pixels emitting light with the same color.

On the other hand, the display device 100 according to the second embodiment of the present disclosure is implemented in a top-emission type, thus is provided with the light emission area with a larger size compared to bottom-emission type, therefore, can further include a common power supply line EVSS for preventing a voltage drop in the center portion of the display panel. The common power supply line EVSS according to one example can function as an auxiliary electrode for further applying a common power source to the cathode electrode 117. As shown in FIG. 10, the common power supply line EVSS according to one example can be disposed at one end of the light emission area EA. For example, in respect with FIG. 10, the common power supply line EVSS can be disposed partially overlapping the light emission area of the first pixel P1 and adjacent to the circuit area of the second pixel P2.

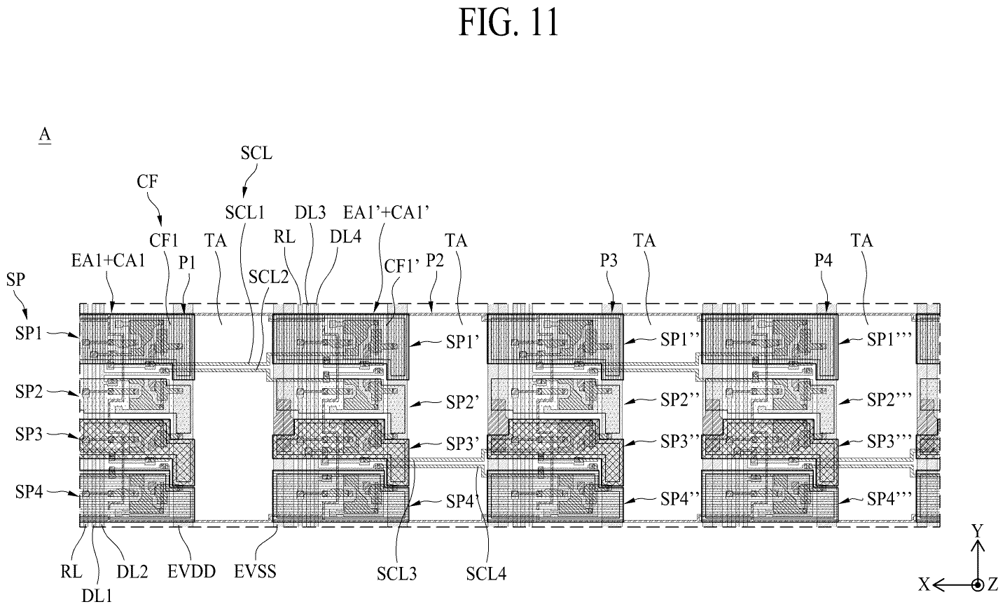

FIG. 11 is a schematic cross-sectional view of a display device according to a third embodiment of the present disclosure.

Referring to FIG. 11, the display device 100 according to a third embodiment of the present disclosure is the same as the display device according to FIG. 10 described above, except that each of the plurality of pixels P (or the plurality of sub-pixels SP) includes a transmission area TA. Accordingly, the same drawing symbols have been assigned to the same configuration, and only the different configurations will be described hereinafter.

The display device according to FIG. 10 is implemented in top-emission type, thus can be configured such that the first color filter CF1 covers the circuit area CA1 (or the first circuit area CA1) and the light emission area EA1 (or the first light emission area EA1) of the first sub-pixel SP1, the second color filter CF2 covers the circuit area CA3 and the light emission area EA3 of the third sub-pixel SP3, and the third color filter CF3 covers the circuit area CA4 and the light emission area EA4 of the fourth sub-pixel SP4. Thus, the display device 100 according to FIG. 10 can be configured with a larger size (or area) of the light emission area of each of the plurality of sub-pixels compared to a case where the color filters cover only the light emission area, and thus, the light emission efficiency can be further improved.

In contrast, the display device according to FIG. 11 can further comprise a transmission area TA for each of the plurality of pixels P (or the plurality of sub-pixels SP). The transmission area TA is an area configured to allow light to transmit through the upper surface and the lower surface of the display panel. Thus, a user facing the upper surface of the display panel can view an image, a background, or the like displaying on the lower surface of the display panel through the transmission area TA. Thus, the display device 100 according to FIG. 11 can be implemented as a transparent display device.

Since the display device 100 according to FIG. 11 can be implemented as a transparent display device of top-emission type, the color filter (or the first color filter CF1) can be configured to cover the light emission area EA (or the first light emission area EA1) and the circuit area CA (or the first circuit area CA1) of the display device of FIG. 1. Thus, in the case of the display device 100 according to FIG. 11, the light emission area of the first sub-pixel SP1 of the first pixel P1 can be represented as the drawing symbol of EA1+CA1. Further, the another first color filter CF1′ of the another first sub-pixel SP1′ of the second pixel P2 can be configured to cover the second circuit area CA1′ and the second light emission area EA1'. Accordingly, the light emission area of the another first sub-pixel SP′ of the second pixel P2 can be represented as a drawing symbol of EA1′+CA1′.

On the other hand, in the display device 100 according to the third embodiment of the present disclosure, the transmission area TA can be disposed between a plurality of light emission areas. For example, the transmission area TA can be disposed between the first color filter CF1 included in the first sub-pixel SP1 of the first pixel P1, and the another first color filter CF1′ included in the another first sub-pixel SP1′ of the second pixel P2. Thus, as shown in FIG. 11, the first share connection line SCL1 can partially overlap the light emission area EA1 of the first sub-pixel SP1 and the transmission area TA of the first sub-pixel SP1. Further, the second share connection line SCL2 can partially overlap the light emission area EA1 of the first sub-pixel SP1 and the transmission area TA of the first sub-pixel SP1. Each of the third share connection line SCL3 and the fourth share connection line SCL4 can partially overlap the light emission area EA′ and the transmission area TA of the another third sub-pixel SP3′ of the second pixel P2. As a result, the display device 100 according to the third embodiment of the present disclosure can be implemented as a transparent display device, thus can have a structural feature in which each of the plurality of share connection lines SCLs partially overlap the light emission area and the transmission area.

Accordingly, in the display device 100 according to the third embodiment of the present disclosure, two sub-pixels (e.g., the first sub-pixel SP1 and the other first sub-pixel SP1′) emitting light with the same color and disposed adjacent to each other are configured to share one data line (e.g., the first data line DL1), thereby reducing the number of drive ICs, reducing manufacturing costs, and no being occurred data swing, therefore the display device can be implemented as a transparent display device improving the lifetime of the drive ICs.

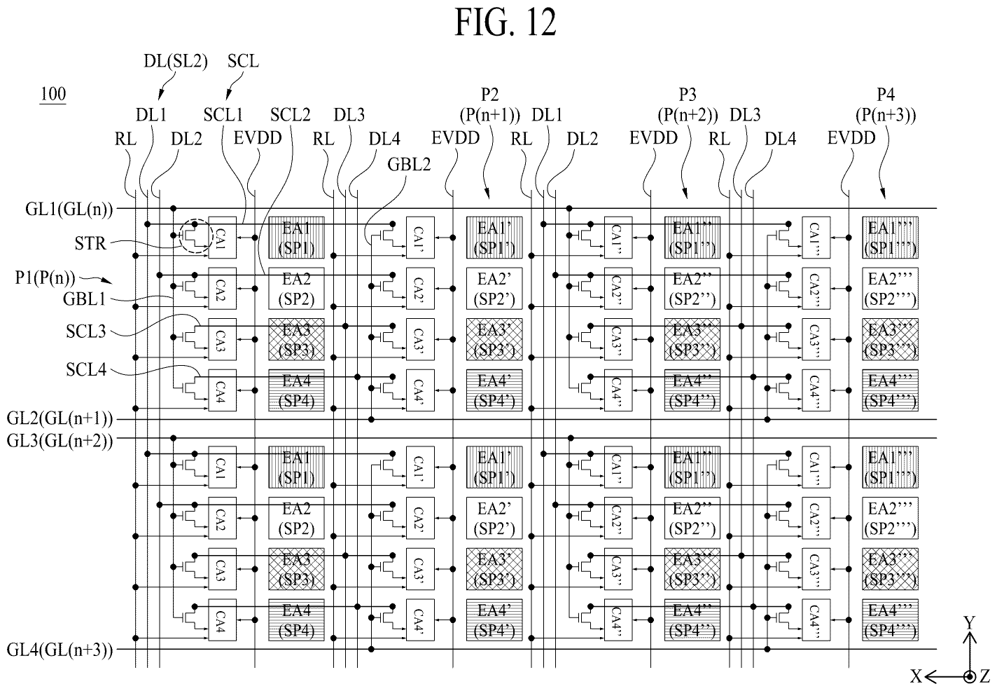

FIG. 12 is a schematic plan view illustrating an example variation of a display device according to one embodiment of the present disclosure.

Referring to FIG. 12, a variant example of the display device 100 according to one embodiment of the present disclosure is the same as the display device according to FIG. 1 described above, except that the connection structure of each of the third share connection line SCL3 and the fourth share connection line SCL4 is changed. Therefore, the same drawing symbols have been assigned to the same configuration, and only the different configurations will be described hereinafter.

In the display device according to FIG. 1 described above, the third share connection line SCL3 can connect the third data line DL3 to each of the circuit area CA3′ of the another third sub-pixel SP3′ of the second pixel P2 and the circuit area CA3″ of the another third sub-pixel SP3″ of the third pixel P3. Thus, the third share connection line SCL3 can partially overlap the light emission area EA3′ of the another third sub-pixel SP3′ of the second pixel P2. Further, the fourth share connection line SCLA can connect the fourth data line DLA to each of the circuit area CA4″ of the another fourth sub-pixel SP4′ of the second pixel P2 and the circuit area CA4′ of the another fourth sub-pixel SP4″ of the third pixel P3. Thus, the fourth share connection line SCL4 can partially overlap the light emission area EA4′ of the another fourth sub-pixel SP4′ of the second pixel P2. Thus, in the display device according to FIG. 1, the another first sub-pixel SP3′ of the second pixel P2 and the another third sub-pixel SP3″ of the third pixel P3 are configured to share the third data line DL3 disposed between the first pixel P1 and the second pixel P2, and the another fourth sub-pixel SP4′ of the second pixel P2 and the another fourth sub-pixel SP4″ of the third pixel P3 can be configured to share the fourth data line DL4 disposed between the first pixel P1 and the second pixel P2.

In contrast, in the case of the display device according to FIG. 12, the third share connection line SCL3 can connect the third data line DL3 to each of the circuit area CA3 of the third sub-pixel SP3 of the first pixel P1 and the circuit area CA3′ of the another first sub-pixel SP3′ of the second pixel P2, respectively. Thus, as shown in FIG. 12, the third share connection line SCL3 can partially overlap the light emission area EA3 of the third sub-pixel SP3 of the first pixel P1. Further, the third share connection line SCL3 can be disposed to extend to each of the third sub-pixel SP3 of the first pixel P1 and the another third sub-pixel SP3′ of the second pixel P2 in respect with the third data line DL3. In other words, the third share connection line SCL3 can extend to both sides in respect with the third data line DL3.

In the case of the display device according to FIG. 12, the fourth share connection line SCLA can connect the fourth data line DL4 to each of the circuit area CA4 of the fourth sub-pixel SP4 of the first pixel P1 and the circuit area CA4′ of the another fourth sub-pixel SP4′ of the second pixel P2. Thus, as shown in FIG. 12, the fourth share connection line SCL4 can partially overlap the light emission area EA4 of the fourth sub-pixel SP4 of the first pixel P1. Further, the fourth share connection line SCL4 can be disposed to extend to each of the fourth sub-pixel SP4 of the first pixel P1 and the another fourth sub-pixel SP4′ of the second pixel P2 in respect with the fourth data line DLA. In other words, the fourth share connection line SCLA can extend to both sides in respect with the fourth data line DL4.

As a result, the variant example of the display device 100 according to one embodiment of the present disclosure can be configured such that the gate of the scan transistor STR of each of the first pixel P1 (or the first pixel Pn) and the third pixel P3 (or the third pixel Pn+2) connects to the first gate line GL1 (or the first gate line GLn), and the gate of the scan transistor STR of each of the second pixel P2 (or the second pixel Pn+1) and the fourth pixel P4 (or the fourth pixel Pn+3) connects to the second gate line GL2 (or the second gate line (GLn+1).

Further, the variant example of the display device 100 according to one embodiment of the present disclosure can be configured such that each of the another first sub-pixel SP1′, the another second sub-pixel SP2′, the another third sub-pixel SP3′, and the another fourth sub-pixel SP4′ of the second pixel P2 (or the second pixel Pn+1) can be configured to share the data line (or the first data line DL1 and the second data line DL2 and the third data line DL3 and the fourth data line DL4) with each of the first sub-pixel SP1, the second sub-pixel SP2, the third sub-pixel SP3, and the fourth sub-pixel SP4 of the first pixel P1 (or the first pixel Pn).

Accordingly, the variant example of the display device 100 according to one embodiment of the present disclosure can be configured such that two sub-pixels (e.g., the first sub-pixel SP1 and the another first sub-pixel SP1′) emitting light with the same color and disposed adjacent to each other share one data line (e.g., the first data line DL1), thus can reduce the number of drive ICs, and reducing manufacturing costs, thus data swing cannot occur, therefore can improve the lifetime of the drive ICs.

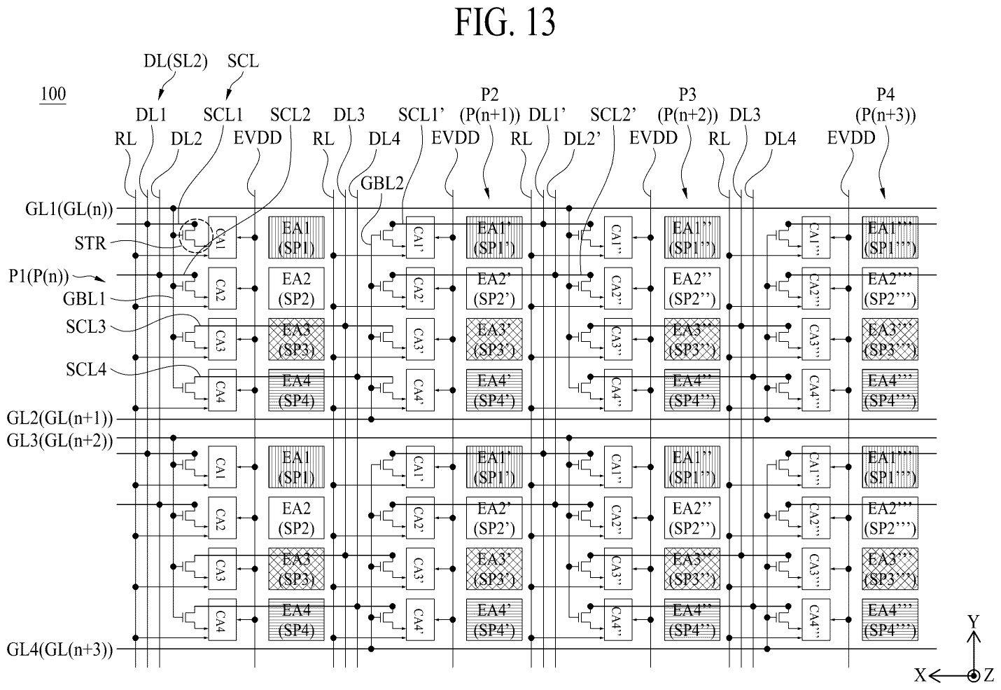

FIG. 13 is a schematic plan view illustrating another example variation of a display device according to one embodiment of the present disclosure.

Referring to FIG. 13, another variant example of the display device 100 according to one embodiment of the present disclosure is the same as the display device according to FIG. 12 described above, except that the connection structure of each of the first share connection line SCL1 and the second share connection line SCL2 is changed. Therefore, the same drawing symbols have been assigned to the same configuration, and only the different configurations will be described hereinafter.

The display device according to FIG. 12 can be configured such that each of the another first sub-pixel SP1′, the another second sub-pixel SP2′, the another third sub-pixel SP3′, and the another fourth sub-pixel SP4′ of the second pixel P2 (or the another second pixel Pn+1) shares the data line (or the first data line DL1 and the second data line DL2 and the third data line DL3 and the fourth data line DL4) with each of the first sub-pixel SP1, the second sub-pixel SP2, the third sub-pixel SP3, and the fourth sub-pixel SP4 of the first pixel P1 (or the first pixel Pn) through the first share connection line SCL1, the second share connection line SCL2, the third share connection line SCL3, and the fourth share connection line SCL4.

In contrast, in the display device according to FIG. 13, the first share connection line SCL1 can connect the first data line DL1 to the circuit area CA1 of the first sub-pixel SP1 of the first pixel P1, and a circuit area of the first sub-pixel of another pixel adjacent to the left side of the first pixel P1. Further, the second share connection line SCL2 can connect the second data line DL2 to the circuit area CA2 of the second sub-pixel SP2 of the first pixel P1, and to a circuit area of another second sub-pixel of another pixel adjacent to the left side of the first pixel P1 Accordingly, the second pixel P2 and the third pixel P3 will be described as an example, in the display device according to FIG. 13, another first share connection line SCL1′ can connect another first data line DL1′ disposed between the another first sub-pixel SP1′ of the second pixel P2 and the another third sub-pixel SP1″ of the third pixel P3 to each of the circuit area CA1′ of the another first sub-pixel SP1′ of the second pixel P2 and the circuit area CA1″ of the another first sub-pixel SP1″ of the third pixel P3.

On the other hand, the another pixel can be disposed opposite to the second pixel P2 in respect with the first pixel P1 and adjacent to the first pixel P1, thus can be another second pixel, in this case, the another second pixel can include another first sub-pixel. Accordingly, the light emission area of the another first sub-pixel included in the another second pixel can be a second light emission area. Therefore, in the case of the display device according to FIG. 13, the first share connection line SCL1 can be configured in a structure in which the first share connection line SCL1 partially overlaps the second light emission area of the another first sub-pixel.

The another first share connection line SCL1′ can partially overlap the light emission area EA1′ (or the second light emission area EA1′) of the another first sub-pixel SP1′ of the second pixel P2. Accordingly, the display device 100 according to FIG. 13 can be configured in a structure in which the another first share connection line SCL1′ is disposed to extend to each of the another first sub-pixel SP1′ of the second pixel P2 and the another first sub-pixel SP1″ of the third pixel P3 in respect with the another first data line DL1′.

Further, in the case of the display device according to FIG. 13, another second share connection line SCL2′ can connect another second data line DL2′ disposed between the another first sub-pixel SP1′ of the second pixel P2 and the another first sub-pixel SP1″ of the third pixel P3 to each of the circuit area CA2′ of the another second sub-pixel SP2′ of the second pixel P2 and the circuit area CA2″ of the another second sub-pixel SP2″ of the third pixel P3. Thus, as shown in FIG. 13, the another second share connection line SCL2′ can partially overlap the light emission area EA2′ of the another second sub-pixel SP2′ of the second pixel P2. Therefore, the display device 100 according to FIG. 13 can be configured in a structure in which the another second share connection line SCL2′ disposed to extend to each of the another second sub-pixel SP2′ of the second pixel P2 and the another second sub-pixel SP2″ of the third pixel P3 in respect with the another second data line DL2′.

As a result, another variant example of the display device 100 according to one embodiment of the present disclosure can be configured such that each of the another first sub-pixel SP1′ and the another second sub-pixel SP2′ of the second pixel P2 (or the second pixel Pn+1) shares a data line (or another first data line DL1′ and another second data line DL2′) with each of the another first sub-pixel SP1″ and the another second sub-pixel SP2″ of the third pixel P3 (or the third pixel Pn+2), and each of the another third sub-pixel SP3′ and the another fourth sub-pixel SP4′ of the second pixel P2 (or the second pixel Pn+1) shares a data line (or another third data line DL3′ and another fourth data line DL4′) with each of the another third sub-pixel SP3 and the another fourth sub-pixel SP4 of the first pixel P1 (or the first pixel Pn).

Accordingly, another variants of the display device 100 according to one embodiment of the present disclosure can be configured such that two sub-pixels (e.g., the another first sub-pixel SP1′ and the another first sub-pixel SP1″) emitting light with the same color and disposed adjacent to each other share one data line (e.g., the another first data line DL1′), thereby reducing the number of drive ICs, and reducing manufacturing costs, thus data swing cannot occur, therefore can improve the lifetime of the drive ICs.

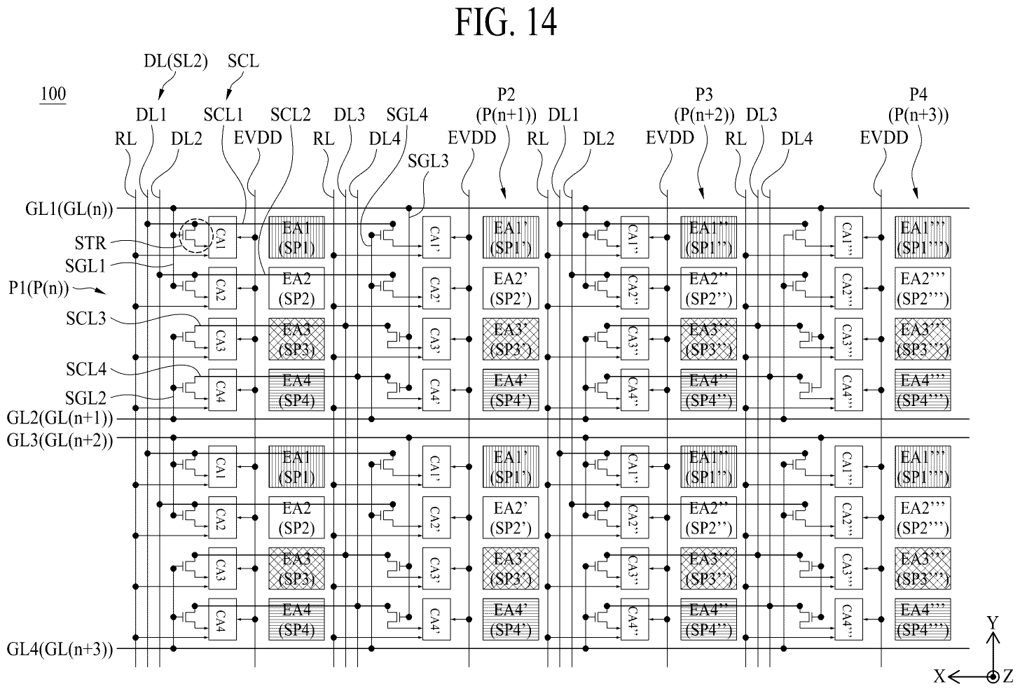

FIG. 14 is a schematic plan view illustrating another example variation of a display device according to one embodiment of the present disclosure.

Referring to FIG. 14, another variant example of the display device 100 according to one embodiment of the present disclosure is the same as the display device according to FIG. 12 described above, except that the connection structure of the gate line GL and the scan transistor of each of the plurality of sub-pixels SP has been changed. Therefore, the same drawing symbols have been assigned to the same configuration, and only the different configurations will be described hereinafter.

In the case of the display device according to FIG. 12 described above, the gate of the scan transistors STR included in each of the first pixel P1 (or the first pixel Pn) and the third pixel P3 (or the third pixel Pn+2) can be configured to be connected to the first gate line GL1 (or the first gate line GLn), and the gate of the scan transistors STR included in each of the second pixel P2 (or the second pixel Pn+1) and the fourth pixel P4 (or the fourth pixel Pn+3) can be configured to be connected to the second gate line GL2 (or the second gate line GLn+1). Thus, in the case of the display device according to FIG. 12, each of the first pixel P1 (or the first pixel Pn) and the third pixel P3 (or the third pixel Pn+2) can be applied with a gate signal from the first gate line GL1 (or the first gate line GLn). Further, each of the second pixel P2 (or the second pixel Pn+1) and the fourth pixel P4 (or the fourth pixel Pn+3) can be applied with a gate signal from the second gate line GL2 (or the second gate line GLn+1).

In contrast, the display device according to FIG. 14 can include a first sub-gate branch line SGL1 connecting the first gate line GL1 to each of the first sub-pixel SP1 (or the scan transistor STR of the first sub-pixel SP1) and the second sub-pixel SP2 (or the scan transistor STR of the second sub-pixel SP2) of the first pixel P1, and a second sub-gate branch line SGL2 connecting the second gate line GL2 to each of the third sub-pixel SP3 (or the scan transistor STR of the third sub-pixel SP3) and the fourth sub-pixel SP4 (or the scan transistor STR of the fourth sub-pixel SP4) of the first pixel P1. Further, the display device according to FIG. 14 can include a third sub-gate branch line SGL3 connecting the first gate line GL1 to each of the another third sub-pixel SP3′ (or the scan transistor STR of the another third sub-pixel SP3′) and the another fourth sub-pixel SP4′ (or the scan transistor STR of the another fourth sub-pixel SP4′) of the second pixel P2 and a fourth sub-gate branch line SGL4 connecting the second gate line GL2 to each of the another first sub-pixel SP1′ (or scan transistor STR of the another first sub-pixel SP1′) and the another second sub-pixel SP2′ (or scan transistor STR of the another second sub-pixel SP2′) of the second pixel P2.

Thus, in the case of the display device according to FIG. 14, the first sub-pixel SP1 and the second sub-pixel SP2 of the first pixel P1 (or the first pixel Pn), and the another third sub-pixel SP3′ and the another fourth sub-pixel SP4′ of the second pixel P2 (or the second pixel Pn+1) can be applied with a gate signal from the first gate line GL1 (or the first gate line (GLn). Further, the third sub-pixel SP3 and the fourth sub-pixel SP4 of the first pixel P1 (or the first pixel Pn), and the another first sub-pixel SP1′ and the another second sub-pixel SP2′ of the second pixel P2 (or the second pixel Pn+1) can be applied with a gate signal from the second gate line GL2 (or the second gate line GLn+1).

Consequently, in another variant example of the display device 100 according to one embodiment of the present disclosure, the scan transistor of each of the first sub-pixel SP1 and the second sub-pixel SP2 of the first pixel P1 (or first pixel Pn), the another third sub-pixel SP3′ and the another fourth sub-pixel SP4′ of the second pixel P2 (or the second pixel Pn+1), is connected to the first gate line GL1 (or the first gate line GLn). Further, the scan transistor STR of each of the third sub-pixel SP3 and the fourth sub-pixel SP4 of the first pixel P1 (or the first pixel Pn), the another first sub-pixel SP1′ and the another second sub-pixel SP2′ of the second pixel P2 (or the second pixel Pn+1), is connected to the second gate line GL2 (or the second gate line GLn+1).

Accordingly, another variant example of the display device 100 according to one embodiment of the present disclosure can be provided with two sub-pixels (e.g., the first sub-pixel SP1 and the another first sub-pixel SP1′) emitting light with the same color and disposed adjacent to each other to share one data line (e.g., the first data line DL1), thereby reducing the number of drive ICs, and reducing the manufacturing cost, thus data swing cannot occur, therefore can improve the lifetime of the drive ICs. Furthermore, another variant example of the display device 100 according to one embodiment of the present disclosure is that each of the first sub-gate branch line SGL1, the second sub-gate branch line SGL2, the third sub-gate branch line SGL3, and the fourth sub-gate branch line SGL4 is connected to only two sub-pixels, the stress for the gate voltage (or gate signal) can be reduced compared to the case where four sub-pixels are connected to one gate branch line, and thus the service life of the first to fourth sub-gate branch line SGL1, SGL2, SGL3, and SGL4 can be improved.

Meanwhile, in another variant example of the display device 100 according to one embodiment of the present disclosure, the first sub-gate branch line SGL1 is disposed in the same direction (e.g., the second direction Y-axis direction) as the circuit area CA1 (or the first circuit area CA1) of the first sub-pixel SP1 of the first pixel P1 and the circuit area CA2 of the second sub-pixel SP2 of the first pixel P1. Further, the second sub-gate branch line SGL2 can be disposed in the same direction (e.g., the second direction (Y-axis direction)) as the circuit area CA3 of the third sub-pixel SP3 of the first pixel P1 and the circuit area CA4 of the fourth sub-pixel SP4 of the first pixel P1. In this case, in another variant example of the display device 100 according to one embodiment of the present disclosure, the first sub-gate branch line SGL1 and the second sub-gate branch line SGL2 can be contrasted with the first gate branch line GBL1 of the display device according to FIG. 12.

Thus, in another variant example of the display device 100 according to one embodiment of the present disclosure, even if a process deviation occurs, the first sub-gate branch line SGL1 can be spaced apart by the same distance away from or close to the circuit areas CA1, CA2 of each of the first sub-pixel SP1 and the second sub-pixel SP2, and the second sub-gate branch line SGL2 can be spaced apart by the same distance away from or close to the circuit areas CA3, CA4 of each of the third sub-pixel SP3 and the fourth sub-pixel SP4, thus deviations in the gate signals of each of the first to fourth sub-pixels SP1, SP2, SP3, and SP4 cannot occur and image quality degradation can be prevented.

Furthermore, in another variant example of the display device 100 according to one embodiment of the present disclosure, the third sub-gate branch line SGL3 is disposed in the same direction (e.g., the second direction (Y-axis direction)) as each of the another first sub-pixel SP1′, the another second sub-pixel SP2′, the another third sub-pixel SP3′, and the another fourth sub-pixel SP4′ of the second pixel P2, and the fourth sub-gate branch line SGL4 can be disposed farther than the third sub-gate branch line SGL3, but in the same direction (e.g., the second direction (Y-axis direction)) as the circuit areas CA1′, CA2′, CA3′, and CA4′ of each of the another first sub-pixel SP1′, the another second sub-pixel SP2′, the another third sub-pixel SP3′, and the another fourth sub-pixel SP4′ of the second pixel P2. In this case, in another variant example of the display device 100 according to one embodiment of the present disclosure, the third sub-gate branch line SGL3 and/or the fourth sub-gate branch line SGL4 can be contrasted with the second gate branch line GBL2 of the display device according to FIG. 12.

Accordingly, in another variant example of the display device 100 according to one embodiment of the present disclosure, even if a process deviation occurs, the third sub-gate branch line SGL3 and/or the fourth sub-gate branch line SGL4 can be spaced apart by the same distance away from or close to the circuit areas CA1′, CA2′, CA3′, and CA4′ of each of the another first sub-pixel SP1′, the another second sub-pixel SP2′, the another third sub-pixel SP3′, and the another fourth sub-pixel SP4′ of the second pixel P2, thus deviations in the gate signals of each of the another first sub-pixels SP1′, the another second sub-pixels SP2′, the another third sub-pixels SP3′, and the another fourth sub-pixels SP4′ of the second pixel P2 cannot occur, thereby preventing image quality degradation.

Embodiments of the present disclosure have been described in more detail with reference to the accompanying drawings, but the present disclosure is not necessarily limited to these embodiments and can be practiced in various modifications without departing from the technical ideas of the present disclosure. Accordingly, the embodiments disclosed herein are intended to illustrate, not limit, the technical ideas of the present disclosure, and the scope of the technical ideas of the present disclosure is not limited by these embodiments. Therefore, the embodiments described above are exemplary in all respects and should be understood as non-limiting. The scope of the protection of this disclosure shall be construed by the scope of the claims, and all technical ideas within the equivalent scope shall be construed to be included within the scope of the rights of this disclosure.

In this present disclosure, two subpixels emitting light with the same color and disposed adjacent to each other are provided to share one data line, thus reducing the number of drive ICs as well as heat generation of the drive IC can be prevented.

Furthermore, in this present disclosure, since the circuit area of each of the first sub-pixel, the second sub-pixel, the third sub-pixel, and the fourth sub-pixel included in each of the plurality of the pixels is disposed in the same direction as the gate branch line, even if a process deviation occurs, a distance deviation (or parasitic cap deviation) between the gate branch line and the circuit area (or the gate node of the drive transistor) cannot occur, thereby preventing the image quality degradation.

Furthermore, in this present disclosure, two subpixels emitting light with the same color and disposed adjacent to each other are configured to share one data line, thereby improving life span of drive IC, and increasing the overall service life, thus operating at lower power, therefore the overall power consumption can be reduced.

The effects obtained herein are not limited to the effects mentioned above, and other effects not mentioned can be clearly understood by those of ordinary skill in the art to which this disclosure belongs from the description above.

What is claimed is:

1. A display apparatus comprising:
a first pixel comprising a first sub-pixel including a first circuit area and a first light emission area, and disposed in a first direction;
a second pixel disposed adjacent to the first pixel in the first direction, and comprising another first sub-pixel including a second circuit area and a second light emission area and emitting light with the same color as the first sub-pixel;
a first data line disposed on one side of the first circuit area in a second direction; and
a first share connection line connecting the first data line to each of the first circuit area and the second circuit area.

2. The display apparatus of claim 1, wherein the first share connection line partially overlaps with the first light emission area or the second light emission area.

3. The display apparatus of claim 1, wherein the first pixel further comprises:
a second sub-pixel disposed adjacent to the first sub-pixel in the second direction,
a third sub-pixel disposed adjacent to the second sub-pixel in the second direction, and
a fourth sub-pixel disposed adjacent to the third sub-pixel in the second direction,
wherein the first data line extends in the second direction to be disposed adjacent to a circuit area of each of the second sub-pixel, the third sub-pixel, and the fourth sub-pixel and the first circuit area.

4. The display apparatus of claim 3, further comprising:
a first gate branch line disposed between each of the first circuit area, and the circuit area of each of the second sub-pixel, the third sub-pixel and the fourth sub-pixel and the first data line,
wherein the first gate branch line is disposed in a same direction as the circuit area of each of the second sub-pixel, the third sub-pixel, and the fourth sub-pixel and the first circuit area.

5. The display apparatus of claim 4, further comprising:
a first gate line connected to the first gate branch line,
wherein the first gate line extending in the first direction intersecting with the first data line and is disposed adjacent to the first sub-pixel.

6. The display apparatus of claim 4, further comprising:
a second data line disposed between the circuit area of each of the second sub-pixel, the third sub-pixel, and the fourth sub-pixel and the first data line,
wherein the second pixel further comprises another second sub-pixel disposed adjacent to the another first sub-pixel in the second direction; and
a second share connection line connecting the second data line to each of the circuit area of the second sub-pixel and the circuit area of the another second sub-pixel.

7. The display apparatus of claim 6, wherein the second share connection line partially overlaps with a light emission area of the second sub-pixel or a light emission area of the another second sub-pixel.

8. The display apparatus of claim 6, wherein the first gate branch line intersects with the first share connection line and the second share connection line.

9. The display apparatus of claim 6, further comprising:
a third data line extending between the first sub-pixel and the another first sub-pixel in the second direction,
wherein the second pixel further comprises another third sub-pixel disposed adjacent to the another second sub-pixel in the second direction;
a third pixel disposed adjacent to the second pixel in the first direction, and comprising another third sub-pixel emitting light with the same color as the another third sub-pixel of the second pixel; and
a third share connection line connecting the third data line to each of the circuit area of the another third sub-pixel of the second pixel and the circuit area of the another third sub-pixel of the third pixel.

10. The display apparatus of claim 9, wherein the third share connection line partially overlaps with a light emission area of the another third sub-pixel of the second pixel or a light emission area of the third sub-pixel of the first pixel.

11. The display apparatus of claim 9, wherein a portion of the third share connection line overlaps with a portion of the second share connection line in the second direction.

12. The display apparatus of claim 9, further comprising:
a fourth data line disposed between the third data line and the circuit area of each of the another second sub-pixel of the second pixel and the another third sub-pixel of the second pixel,
wherein the second pixel further comprises another fourth sub-pixel disposed adjacent to the another third sub-pixel of the second pixel in the second direction, and
wherein the third pixel further comprises another fourth sub-pixel disposed adjacent to the another third sub-pixel of the third pixel in the second direction; and
a fourth share connection line connecting the fourth data line to each of the circuit area of the another fourth sub-pixel of the second pixel and the circuit area of the another fourth sub-pixel of the third pixel.

13. The display apparatus of claim 12, wherein the fourth share connection line partially overlaps with a light emission area of the another fourth sub-pixel of the second pixel or a light emission area of the fourth sub-pixel of the first pixel.

14. The display apparatus of claim 12, further comprising:
a second gate branch line disposed between the fourth data line and each of the second circuit area, and the circuit area of each of the another second sub-pixel, the another third sub-pixel, and the another fourth sub-pixel of the second pixel,
wherein the second gate branch line is disposed in a same direction as the second circuit area and the circuit area of each of the another second sub-pixel, the another third sub-pixel and the another fourth sub-pixel of the second pixel.

15. The display apparatus of claim 14, further comprising:
a second gate line connected to the second gate branch line,
wherein the second gate line extends in the first direction intersecting with the fourth data line and is disposed adjacent to the another fourth sub-pixel of the second pixel.

16. The display apparatus of claim 14, wherein the second gate branch line intersects with the third share connection line and the fourth share connection line.

17. The display apparatus of claim 1, further comprising:
a first color filter covering the first circuit area and the first light emission area; and
another first color filter covering the second circuit area and the second light emission area,
wherein the first color filter is divided from or connected to the another first color filter.

18. The display apparatus of claim 1, further comprising:
a first color filter covering the first circuit area and the first light emission area;
another first color filter covering the second circuit area and the second light emission area; and
a transmission area disposed between the first color filter and the another first color filter.

19. The display apparatus of claim 18, wherein the first share connection line partially overlaps with the first light emission area and the transmission area.

20. The display apparatus of claim 6, further comprising:
a third data line extending between the first sub-pixel of the first pixel and the another first sub-pixel of the second pixel in the second direction,
wherein the second pixel further comprises another third sub-pixel disposed adjacent to the another second sub-pixel of the second pixel in the second direction; and
a third share connection line connecting the third data line to each of the circuit area of the third sub-pixel of the first pixel and a circuit area of the another third sub-pixel of the second pixel.

21. The display apparatus of claim 20, wherein the third share connection line is disposed to extend to the third sub-pixel of the first pixel and the another third sub-pixel of the second pixel in respect with the third data line.

22. The display apparatus of claim 20, wherein the third share connection line partially overlaps a light emission area of the third sub-pixel of the first pixel.

23. The display apparatus of claim 1, further comprising:
a third pixel disposed adjacent to the second pixel in the first direction, and comprising another first sub-pixel emitting light with the same color as the another first sub-pixel of the second pixel;
another first data line disposed between the another first sub-pixel of the second pixel and the another first sub-pixel of the third pixel; and
another first share connection line connecting the another first data line to each of the second circuit area of the another first sub-pixel of the second pixel and a circuit area of the another first sub-pixel of the third pixel,
wherein the another first share connection line partially overlaps with the second light emission area.

24. The display apparatus of claim 23, wherein the another first share connection line is disposed to extend to the another first sub-pixel of the second pixel and the another first sub-pixel of the third pixel in respect with the another first data line.

25. The display apparatus of claim 3, further comprising:
a first gate line intersecting with the first data line and disposed adjacent to the first sub-pixel;
a second gate line spaced apart the first gate line in parallel and disposed adjacent to the fourth sub-pixel;
a first sub-gate branch line connecting the first gate line to each of the first sub-pixel and the second sub-pixel; and
a second sub-gate branch line connecting the second gate line to each of the third sub-pixel and the fourth sub-pixel.

26. The display apparatus of claim 25, wherein the second pixel further comprises:
another second sub-pixel disposed adjacent to the another first sub-pixel of the second pixel in the second direction;
another third sub-pixel disposed adjacent to the another second sub-pixel of the second pixel in the second direction; and
another fourth sub-pixel disposed adjacent to the another third sub-pixel of the second pixel in the second direction, and
wherein the display apparatus further comprises:
a third sub-gate branch line connecting the first gate line to each of the another third sub-pixel and the another fourth sub-pixel of the second pixel; and
a fourth sub-gate branch line connecting the second gate line to the another first sub-pixel and the another second sub-pixel of the second pixel.

27. A display apparatus comprising:
a first pixel and a second pixel disposed adjacent to each other in a first direction, the first pixel comprising a first sub-pixel including a first circuit area and a first light emission area, the second pixel comprising another first sub-pixel including a second circuit area and a second light emission area, the first sub-pixel and the another first sub-pixel emitting light of the same color;
a first data line extending in a second direction intersecting with the first direction, and disposed on one side of the first circuit area;
a first share connection line connecting the first data line to each of the first circuit area and the second circuit area; and
a first gate line extending in the first direction, and disposed adjacent to the first sub-pixel.

28. The display apparatus of claim 27, wherein the first share connection line partially overlaps the first light emission area or the second light emission area.

29. The display apparatus of claim 27, further comprising:
a third pixel disposed adjacent to the second pixel in the first direction, and comprising another first sub-pixel emitting the light of the same color;
another first data line disposed between the another first sub-pixel of the second pixel and the another first sub-pixel of the third pixel; and
another first share connection line connecting the another first data line to each of the second circuit area of the another first sub-pixel of the second pixel and a circuit area of the another first sub-pixel of the third pixel,
wherein the another first share connection line partially overlaps the second light emission area.
